(19) United States
(12) Patent Application Publication
(10) Pub. No.: US 2026/0002021 A1
(43) Pub. Date: Jan. 1, 2026

(54) RESIN COMPOSITION, PREPREG, FILM WITH RESIN, METAL FOIL WITH RESIN, METAL-CLAD LAMINATE, AND WIRING BOARD

(71) Applicant: PANASONIC INTELLECTUAL PROPERTY MANAGEMENT CO., LTD., Osaka (JP)

(72) Inventors: Hajime OGUSHI, Fukushima (JP); Hayate HIRONO, Fukushima (JP); Takatoshi MITO, Fukushima (JP); Koichi ISAJI, Osaka (JP); Hiroyuki FUJISAWA, Fukushima (JP)

(73) Assignee: PANASONIC INTELLECTUAL PROPERTY MANAGEMENT CO., LTD., Osaka (JP)

(21) Appl. No.: 19/105,266

(22) PCT Filed: Aug. 8, 2023
(86) PCT No.: PCT/JP2023/028967

§ 371 Date: Feb. 20, 2025

(30) Foreign Application Priority Data
Aug. 26, 2022 (JP) 2022-134867

(51) Int. Cl. C08L 51/08; B32B 15/08; C08J 5/24; C08K 5/3472; C08K 5/357; C08K 5/523; C08K 9/06; C08K 13/06; H05K 1/03

(52) U.S. Cl. CPC C08L 51/08; B32B 15/08; C08J 5/249; C08K 13/06; H05K 1/0366; B32B 2250/02; B32B 2457/08; C08J 2351/08; C08J 2471/12; C08K 5/3472; C08K 5/357; C08K 5/523; C08K 9/06; C08L 2201/08; C08L 2203/20

(57) ABSTRACT

A resin composition contains a polyphenylene ether compound (A), a reactive compound (B) having an unsaturated double bond in a molecule, and at least one additive (C) selected from the group consisting of a heavy metal deactivator (C1) having at least one of an amino group and a triazole structure and a phenolic hydroxyl group in a molecule, a phosphite-based antioxidant (C2) having a tertiary butyl group and a phosphite structure in a molecule, and a hindered phenol-based antioxidant (C3) having a tertiary butyl group and a phenolic hydroxyl group in a molecule.

### TECHNICAL FIELD

The present invention relates to a resin composition, a prepreg, a film with resin, a metal foil with resin, a metal-clad laminate, and a wiring board.

### BACKGROUND ART

In various electronic devices, mounting technologies such as higher integration of semiconductor devices to be mounted, higher wiring density, and multi-layering have rapidly progressed along with an increase in the amount of information processed. In addition, wiring boards used in various electronic devices are required to be, for example, high-frequency compatible wiring boards such as a millimeter-wave radar board for in-vehicle use. Substrate materials for forming insulating layers of wiring boards used in various electronic devices are required to have a low dielectric constant and a low dielectric loss tangent in order to increase the signal transmission speed and to decrease the signal transmission loss.

It is known that polyphenylene ether exhibits excellent low dielectric properties such as a low relative dielectric constant and a low dielectric loss tangent and exhibits excellent low dielectric properties such as a low relative dielectric constant and a low dielectric loss tangent in a high frequency band (high frequency region) from the MHz band to the GHz band as well. For this reason, it has been investigated that polyphenylene ether is used, for example, as a high frequency molding material. More specifically, polyphenylene ether is preferably used as a substrate material for forming an insulating layer of a wiring board to be equipped in an electronic device utilizing a high frequency band. Examples of substrate materials containing polyphenylene ether include the resin composition described in Patent Literature 1.

Patent Literature 1 describes a curable resin composition containing a reaction product of polyphenylene ether with an unsaturated carboxylic acid or an acid anhydride, triallyl cyanurate, and a brominated aromatic compound containing at least one imide ring. Patent Literature 1 discloses that a polyphenylene ether-based resin composition that retains the excellent dielectric properties of polyphenylene ether and exhibits excellent flame retardancy, chemical resistance, and heat resistance after curing.

Substrate materials for forming insulating layers of wiring boards are required to afford cured products, which are excellent not only in low dielectric properties but also in adhesive properties to metal foils and interlayer adhesive properties and further have a sufficiently suppressed decrease in interlayer adhesive properties due to heating and moisture absorption.

### CITATION LIST

### Patent Literature

Patent Literature 1: JP H7-166049 A

### SUMMARY OF INVENTION

The present invention has been made in view of such circumstances, and an object thereof is to provide a resin composition that affords a cured product, which is excellent in low dielectric properties, adhesive properties to metal foils, and interlayer adhesive properties and further has a sufficiently suppressed decrease in interlayer adhesive properties due to heating and moisture absorption. Another object of the present invention is to provide a prepreg, a film with resin, a metal foil with resin, a metal-clad laminate, and a wiring board, which are obtained using the resin composition.

An aspect of the present invention is a resin composition that contains a polyphenylene ether compound (A), a reactive compound (B) having an unsaturated double bond in a molecule, and at least one additive (C) selected from the group consisting of a heavy metal deactivator (C1) having at least one of an amino group and a triazole structure and a phenolic hydroxyl group in a molecule, a phosphite-based antioxidant (C2) having a tertiary butyl group and a phosphite structure in a molecule, and a hindered phenol-based antioxidant (C3) having a tertiary butyl group and a phenolic hydroxyl group in a molecule.

The object described above and other objects, features and advantages of the present invention will become apparent from the following detailed description and accompanying drawings.

### BRIEF DESCRIPTION OF DRAWINGS

FIG. 1 is a schematic sectional view illustrating an example of a prepreg according to an embodiment of the present invention.

FIG. 2 is a schematic sectional view illustrating an example of a metal-clad laminate according to an embodiment of the present invention.

FIG. 3 is a schematic sectional view illustrating an example of a wiring board according to an embodiment of the present invention.

FIG. 4 is a schematic sectional view illustrating an example of a metal foil with resin according to an embodiment of the present invention.

FIG. 5 is a schematic sectional view illustrating an example of a film with resin according to an embodiment of the present invention.

### DESCRIPTION OF EMBODIMENTS

Metal-clad laminates and metal foils with resin used in the manufacture of wiring boards and the like include not only an insulating layer but also a metal foil on the insulating layer. Wiring boards also include not only an insulating layer but also wiring on the insulating layer. Examples of the wiring include wiring derived from a metal foil equipped in the metal-clad laminate or the like.

In electronic devices, particularly in small portable devices such as portable communication terminals and notebook computers, diversification, improvement in performance, thinning, and miniaturization have rapidly proceeded. Along with this, in wiring boards used in these products as well, there is a further demand for refinement of conductor wiring, multilayering of conductor wiring layers, thinning, and improvement in performance such as mechanical properties. For this reason, in the wiring boards, it is required that the wirings do not peel off from the insulating layers although provided wirings are refined wirings. In order to meet this requirement, in the wiring boards, it is required that the adhesive properties between wirings and insulating layers are high. Hence, it is required that the adhesive properties between metal foils and insulating layers are high in metal-clad laminates, and substrate materials for forming insulating layers of wiring boards are required to afford cured products exhibiting excellent adhesive properties to metal foils. As described above, wiring boards are required to be multi-layered and are also required to exhibit high interlayer adhesive properties so that delamination between an insulating layer and another insulating layer does not occur when insulating layers are constituted of multiple layers. For this reason, substrate materials for forming insulating layers of the wiring boards are required to afford cured products, which are excellent in adhesive properties between adjacent cured products, namely, interlayer adhesive properties.

Wiring boards used in various electronic devices are also required to be hardly affected by changes in the external environment. The wiring boards are also required to be excellent in interlayer adhesive properties such that delamination does not occur in an environment having a relatively high humidity as well as an environment having a relatively high temperature, and thus for example, the wiring boards can be used in an environment having a high humidity as well as an environment having a high temperature. Hence, substrate materials for forming insulating layers of wiring boards are required to afford cured products that maintain excellent interlayer adhesive properties when absorbing moisture as well as being heated.

As a result of extensive studies, the present inventors have found out that the objects such as providing a resin composition that affords a cured product, which is excellent in low dielectric properties, adhesive properties to metal foils, and interlayer adhesive properties and further has a sufficiently suppressed decrease in interlayer adhesive properties due to heating and moisture absorption, are achieved by the present invention below.

As described above, wiring boards are required to be excellent in interlayer adhesive properties, and further required to maintain the excellent interlayer adhesive properties when affected by changes in the external environment as well. According to the studies by the present inventors, it has been found out that the interlayer adhesive properties may be insufficient depending on the composition of the resin composition in a case where a resin composition containing polyphenylene ether is used as a substrate material for forming an insulating layer of a wiring board. For example, in a wiring board or the like obtained by using a resin composition containing a reaction product of polyphenylene ether and an unsaturated carboxylic acid or an acid anhydride as a polyphenylene ether component as described in Patent Literature 1, it has been found out that interlayer adhesive properties may be insufficient. It is considered that the reaction product has a carboxyl group in the molecule. It is considered that the reaction product having a carboxyl group in the molecule acts on a metal foil or the like in contact with an insulating layer containing a cured product of the resin composition, causing the components constituting the metal foil to be eluted into the insulating layer. For example, in a case where the metal foil is a chromate-treated copper foil, it is considered that the reaction product acts on the metal foil, causing the chromium component to be eluted from the metal foil into the insulating layer. Moreover, when a wiring board is manufactured, and the like, for example, in a case where the metal foil is removed from the metal-clad laminate and an insulating layer is further formed thereon, it is considered that the eluted components remain in the insulating layer at the portion from which the metal foil has been removed, and these components decrease the interlayer adhesive properties. In a case where not only such components derived from the metal foil of a metal-clad laminate but also components that may reduce interlayer adhesive properties are present, it has been found out that it is possible to enhance interlayer adhesive properties and further to sufficiently suppress a decrease in the interlayer adhesive properties due to changes in the external environment, and the like depending on the additives contained in the resin composition. From these findings, the present invention as described below has been conceived of.

### [Resin Composition]

The resin composition according to an embodiment of the present invention is a resin composition that contains a polyphenylene ether compound (A), a reactive compound (B) having an unsaturated double bond in the molecule, and at least one additive (C) selected from the group consisting of a heavy metal deactivator (C1) having at least one of an amino group and a triazole structure and a phenolic hydroxyl group in the molecule, a phosphite-based antioxidant (C2) having a tertiary butyl group and a phosphite structure in the molecule, and a hindered phenol-based antioxidant (C3) having a tertiary butyl group and a phenolic hydroxyl group in the molecule. By being cured, the resin composition affords a cured product, which is excellent in low dielectric properties, adhesive properties to metal foils, and interlayer adhesive properties and further has a sufficiently suppressed decrease in interlayer adhesive properties due to heating and moisture absorption.

By curing the polyphenylene ether compound (A) together with the reactive compound (B), it is considered that the resin composition can be suitably cured, and a cured product is obtained which is excellent in adhesive properties to metal foils while maintaining the excellent low dielectric properties of the polyphenylene ether chain in the polyphenylene ether compound (A). Furthermore, by containing the additive (C) in the resin composition, it is considered that a decrease in interlayer adhesive properties can be suppressed even when a component that may decrease interlayer adhesive properties is present. It is therefore considered that the interlayer adhesive properties can be enhanced, and further, the decrease in interlayer adhesive properties due to heating and moisture absorption can be sufficiently suppressed. From these facts, it is considered that the resin composition affords a cured product, which is excellent in low dielectric properties, adhesive properties to metal foils, and interlayer adhesive properties and further has a sufficiently suppressed decrease in interlayer adhesive properties due to heating and moisture absorption.

### (Polyphenylene Ether Compound (A))

The polyphenylene ether compound (A) is not particularly limited as long as it is a polyphenylene ether compound having a polyphenylene ether chain in the molecule. The polyphenylene ether compound (A) preferably has, for example, a repeating unit represented by the following Formula (1) in the molecule.

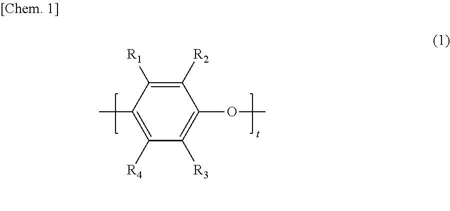

In Formula (1), t represents 1 to 50. R₁ to R₄ are independent of each other. In other words, R₁ to R₄ may be the same group as or different groups from each other. R₁ to R₄ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

Specific examples of the respective functional groups mentioned in R₁ to R₄ include the following.

The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

The alkenyl group is not particularly limited and is, for example, preferably an alkenyl group having 2 to 18 carbon atoms and more preferably an alkenyl group having 2 to 10 carbon atoms. Specific examples thereof include a vinyl group, an allyl group, and a 3-butenyl group.

The alkynyl group is not particularly limited and is, for example, preferably an alkynyl group having 2 to 18 carbon atoms and more preferably an alkynyl group having 2 to 10 carbon atoms. Specific examples thereof include an ethynyl group and a prop-2-yn-1-yl group (propargyl group).

The alkylcarbonyl group is not particularly limited as long as it is a carbonyl group substituted with an alkyl group and is, for example, preferably an alkylcarbonyl group having 2 to 18 carbon atoms and more preferably an alkylcarbonyl group having 2 to 10 carbon atoms. Specific examples thereof include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as it is a carbonyl group substituted with an alkenyl group and is, for example, preferably an alkenylcarbonyl group having 3 to 18 carbon atoms and more preferably an alkenylcarbonyl group having 3 to 10 carbon atoms. Specific examples thereof include an acryloyl group, a methacryloyl group, and a crotonoyl group.

The alkynylcarbonyl group is not particularly limited as long as it is a carbonyl group substituted with an alkynyl group and is, for example, preferably an alkynylcarbonyl group having 3 to 18 carbon atoms and more preferably an alkynylcarbonyl group having 3 to 10 carbon atoms. Specific examples thereof include a propioloyl group.

The weight average molecular weight (Mw) and number average molecular weight (Mn) of the polyphenylene ether compound (A) are not particularly limited, and for example, are preferably 500 to 5,000, preferably 800 to 4,000, preferably 1,000 to 3,000. When the molecular weight is too low, sufficient heat resistance of the cured product tends to be hardly attained. When the molecular weight is too high, there is a tendency that the melt viscosity of the resin composition is high, sufficient fluidity is not attained, and molding defects cannot be sufficiently suppressed. Hence, when the weight average molecular weight of the polyphenylene ether compound is in the above range, excellent heat resistance and moldability of the cured product can be realized. Here, the weight average molecular weight and number average molecular weight may be those measured by general molecular weight measurement methods, and specific examples thereof include values measured by gel permeation chromatography (GPC). In a case where the polyphenylene ether compound has a repeating unit represented by Formula (1) in the molecule, t is preferably a numerical value so that the weight average molecular weight and number average molecular weight of the polyphenylene ether compound is in the above range. Specifically, t is preferably 1 to 50.

Examples of the polyphenylene ether compound (A) include a polyphenylene ether compound (A1) having at least one selected from the group consisting of a hydroxyl group, a carboxyl group, an unsaturated double bond group, and an ester bond in the molecule and a preliminary reaction product (A2) obtained by previously reacting a mixture containing a polyphenylene ether compound (a2-1) having at least one selected from the group consisting of a hydroxyl group, a carboxyl group, and an ester bond in the molecule and a compound (a2-2) that reacts with at least one of a hydroxyl group, a carboxyl group, and an ester bond. The polyphenylene ether compound (A) is capable of reacting with the reactive compound (B). The resin composition is cured as the polyphenylene ether compound (A) reacts with the reactive compound (B).

### (Polyphenylene Ether Compound (A1))

The polyphenylene ether compound (A1) is not particularly limited as long as it is a polyphenylene ether compound having at least one selected from the group consisting of a hydroxyl group, a carboxyl group, an unsaturated double bond group, and an ester bond in the molecule. Examples of the polyphenylene ether compound (A1) include a polyphenylene ether compound having a hydroxyl group in the molecule (hydroxyl group-containing polyphenylene ether compound) (A1-1), a polyphenylene ether compound having a carboxyl group in the molecule (carboxyl group-containing polyphenylene ether compound) (A1-2), a polyphenylene ether compound having an unsaturated double bond group in the molecule (unsaturated double bond-containing polyphenylene ether compound) (A1-3), and a polyphenylene ether compound having an ester bond in the molecule (ester bond-containing polyphenylene ether compound) (A1-4). Examples of the polyphenylene ether compound (A1) also include a polyphenylene ether compound having two or more of a hydroxyl group, a carboxyl group, an unsaturated double bond group, or an ester bond in the molecule, such as a polyphenylene ether compound having a hydroxyl group and a carboxyl group in the molecule (hydroxyl group/carboxyl group-containing polyphenylene ether compound) (A1-5).

### (Hydroxyl Group-Containing Polyphenylene Ether Compound (A1-1))

The hydroxyl group-containing polyphenylene ether compound (A1-1) is not particularly limited as long as it is a polyphenylene ether compound having a hydroxyl group in the molecule. The hydroxyl group-containing polyphenylene ether compound (A1-1) is preferably a polyphenylene ether compound having a hydroxyl group at the molecular terminal. Specific examples of the hydroxyl group-containing polyphenylene ether compound (A1-1) include a polyphenylene ether compound represented by the following Formula (2) and a polyphenylene ether compound represented by the following Formula (3).

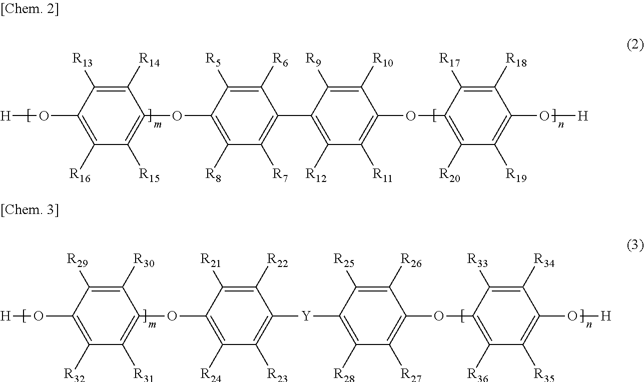

In Formulas (2) and (3), R₅ to R₂₀ and R₂₁ to R₃₆ are independent of each other. In other words, R₅ to R₂₀ and R₂₁ to R₃₆ may be the same group as or different groups from each other. Examples of R₅ to R₂₀ and R₂₁ to R₃₆ include those the same as R₁ to R₄ in Formula (1). In other words, R₅ to R₂₀ and R₂₁ to R₃₆ represent a hydrogen atom, an alkyl group, an alkenyl group, an alkynyl group, a formyl group, an alkylcarbonyl group, an alkenylcarbonyl group, or an alkynylcarbonyl group. In Formula (3), Y represents a linear, branched, or cyclic hydrocarbon having 20 or less carbon atoms. m and n each preferably represent 0 to 20. In addition, it is preferable that m and n represent numerical values so that the sum of m and n is 1 to 30. Hence, it is more preferable that m represents 0 to 20, n represents 0 to 20, and the sum of m and n represents 1 to 30.

In Formula (3), Y represents a linear, branched, or cyclic hydrocarbon having 20 or less carbon atoms as described above. Examples of Y include a group represented by the following Formula (4).

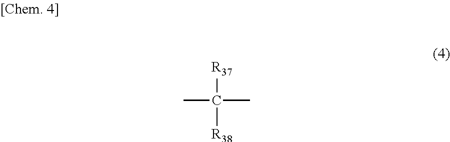

In Formula (4), R₃₇ and R₃₈ each independently represent a hydrogen atom or an alkyl group. Examples of the alkyl group include a methyl group. Examples of the group represented by Formula (4) include a methylene group, a methylmethylene group, and a dimethylmethylene group. Among these, a dimethylmethylene group is preferable.

More specific examples of the polyphenylene ether compound represented by Formula (2) include a polyphenylene ether compound represented by the following Formula (5). More specific examples of the polyphenylene ether compound represented by Formula (3) include a polyphenylene ether compound represented by the following Formula (6).

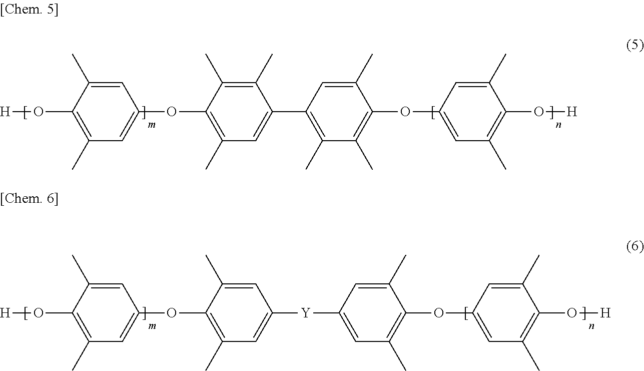

In Formulas (5) and (6), m and n are the same as m and n in Formulas (2) and (3), and specifically, m and n each preferably represent 0 to 20. In Formula (6), Y is the same as Y in Formula (3).

### (Carboxyl Group-Containing Polyphenylene Ether Compound (A1-2) and Hydroxyl Group/Carboxyl Group-Containing Polyphenylene Ether Compound (A1-5))

The carboxyl group-containing polyphenylene ether compound (A1-2) is not particularly limited as long as it is a polyphenylene ether compound having a carboxyl group in the molecule. The carboxyl group-containing polyphenylene ether compound (A1-2) is preferably a polyphenylene ether compound having a carboxyl group at the molecular terminal. The hydroxyl group/carboxyl group-containing polyphenylene ether compound (A1-5) is not particularly limited as long as it is a polyphenylene ether compound having a hydroxyl group and a carboxyl group in the molecule. The hydroxyl group/carboxyl group-containing polyphenylene ether compound (A1-5) is preferably a polyphenylene ether compound having each of a hydroxyl group and a carboxyl group at the molecular terminal. Examples of the carboxyl group-containing polyphenylene ether compound (A1-2) and the hydroxyl group/carboxyl group-containing polyphenylene ether compound (A1-5) include a preliminary reaction product obtained by previously reacting a mixture containing a hydroxyl group-containing polyphenylene ether compound and an acid anhydride having an acid anhydride group in the molecule as described later. In other words, examples of the carboxyl group-containing polyphenylene ether compound (A1-2) and the hydroxyl group/carboxyl group-containing polyphenylene ether compound (A1-5) include a reaction product obtained by reacting the hydroxyl group-containing polyphenylene ether compound with the acid anhydride. The carboxyl group-containing polyphenylene ether compound (A1-2) is one obtained when all of the hydroxyl groups in the hydroxyl group-containing polyphenylene ether compound are converted to substituents having a carboxyl group by the acid anhydride. The hydroxyl group/carboxyl group-containing polyphenylene ether compound (A1-5) is one obtained when some of the hydroxyl groups in the hydroxyl group-containing polyphenylene ether compound are converted to substituents having a carboxyl group by the acid anhydride.

### (Unsaturated Double Bond Group-Containing Polyphenylene Ether Compound (A1-3))

The unsaturated double bond group-containing polyphenylene ether compound (A1-3) is not particularly limited as long as it is a polyphenylene ether compound having an unsaturated double bond group in the molecule. Examples of the unsaturated double bond group-containing polyphenylene ether compound (A1-3) include a modified polyphenylene ether compound having a terminal modified with a substituent having an unsaturated double bond. Examples of the unsaturated double bond-modified polyphenylene ether compound include those obtained by modifying the terminal of the hydroxyl group-containing polyphenylene ether compound (A1-1) with a substituent having an unsaturated double bond, and more specific examples thereof include a polyphenylene ether compound (styrene-modified polyphenylene ether) having a vinylbenzyl group (ethenylbenzyl group) at the molecular terminal, a polyphenylene ether compound (acryl-modified polyphenylene ether) having an acryloyl group at the molecular terminal, and a polyphenylene ether compound (methacryl-modified polyphenylene ether) having a methacryloyl group at the molecular terminal.

### (Ester Bond-Containing Polyphenylene Ether Compound (A1-4))

The ester bond-containing polyphenylene ether compound (A1-4) is not particularly limited as long as it is a polyphenylene ether compound having an ester bond in the molecule.

### (Preliminary Reaction Product (A2))

The preliminary reaction product (A2) is not particularly limited as long as it is a preliminary reaction product obtained by previously reacting a mixture containing a polyphenylene ether compound (a2-1) having at least one selected from the group consisting of a hydroxyl group, a carboxyl group, and an ester bond in the molecule and a compound (a2-2) that reacts with at least one of a hydroxyl group, a carboxyl group, and an ester bond. The compound (a2-2) is not particularly limited as long as it is a compound that reacts with at least one of a hydroxyl group, a carboxyl group, and an ester bond, and examples thereof include an acid anhydride (a2-2-1) having an acid anhydride group in the molecule and a carbodiimide compound (a2-2-2). Examples of the preliminary reaction product (A2) include a preliminary reaction product (A2-1) obtained by previously reacting a mixture containing a polyphenylene ether compound having a hydroxyl group in the molecule and an acid anhydride having an acid anhydride group in the molecule, and a preliminary reaction product (A2-2) obtained by previously reacting a mixture containing a polyphenylene ether compound having at least one of a hydroxyl group and a carboxyl group in the molecule and a carbodiimide compound.

### (Preliminary Reaction Product (A2-1))

The preliminary reaction product (A2-1) is not particularly limited as long as it is a preliminary reaction product obtained by previously reacting a mixture containing a hydroxyl group-containing polyphenylene ether compound (a2-1-1) having a hydroxyl group in the molecule and an acid anhydride (a2-2-1) having an acid anhydride group in the molecule. The preliminary reaction product (A2-1) is, for example, only required to be obtained by previously reacting the hydroxyl group-containing polyphenylene ether compound (a2-1-1) with the acid anhydride (a2-2-1), and may be a reaction product obtained by previously reacting the hydroxyl group-containing polyphenylene ether compound (a2-1-1) with the acid anhydride (a2-2-1) and also a compound (another raw material) (a2-3-1) capable of reacting with at least one of the hydroxyl group-containing polyphenylene ether compound (a2-1-1) and the acid anhydride (a2-2-1). Examples of the hydroxyl group-containing polyphenylene ether compound (a2-1-1) include the hydroxyl group-containing polyphenylene ether compound (A1-1). The carboxyl group-containing polyphenylene ether compound (A1-2) is one obtained when all of the hydroxyl groups in the hydroxyl group-containing polyphenylene ether compound (a2-1-1) are converted to substituents having a carboxyl group by the acid anhydride (a2-2-1). The hydroxyl group/carboxyl group-containing polyphenylene ether compound (A1-5) is one obtained when some of the hydroxyl groups in the hydroxyl group-containing polyphenylene ether compound (a2-1-1) are converted to substituents having a carboxyl group by the acid anhydride (a2-2-1).

The preliminary reaction product (A2-1) is, for example, only required to be obtained by previously reacting the hydroxyl group-containing polyphenylene ether compound (a2-1-1) with the acid anhydride (a2-2-1), and may be a reaction product obtained by previously reacting the hydroxyl group-containing polyphenylene ether compound (a2-1-1) with the acid anhydride (a2-2-1) and also a compound (another raw material) (a2-3-1) capable of reacting with at least one of the hydroxyl group-containing polyphenylene ether compound (a2-1-1) and the acid anhydride (a2-2-1). In other words, examples of the preliminary reaction product (A2-1) include a reaction product (A2-1-4) obtained by reacting the hydroxyl group-containing polyphenylene ether compound (a2-1-1) with the acid anhydride (a2-2-1) and a reaction product (A2-1-5) obtained by reacting the hydroxyl group-containing polyphenylene ether compound (a2-1-1) with the acid anhydride (a2-2-1) and the other raw material (a2-3-1). The mixture is only required to contain the hydroxyl group-containing polyphenylene ether compound (a2-1-1) and the acid anhydride (a2-2-1), and may further contain the other raw material (a2-3-1). The preliminary reaction product (A2-1) is only required to include at least one of the reaction product (A2-1-4) and the reaction product (A2-1-5). The preliminary reaction product (A2-1) may contain the unreacted hydroxyl group-containing polyphenylene ether compound (a2-1-1), the unreacted acid anhydride (a2-2-1), or the unreacted other raw material (a2-3-1). The other raw material (a2-3-1) is not particularly limited as long as it is a compound capable of reacting with at least one of the hydroxyl group-containing polyphenylene ether compound (a2-1-1) and the acid anhydride (a2-2-1).

The acid anhydride (a2-2-1) is not particularly limited as long as it is an acid anhydride having an acid anhydride group in the molecule. The acid anhydride group may have a structure obtained by dehydration condensation of carboxylic acids in different molecules, or may have a structure obtained by dehydration condensation of two carboxylic acids in the molecule. The acid anhydride (a2-2-1) may be an acid anhydride (monofunctional acid anhydride) having one acid anhydride group in the molecule, or an acid anhydride (polyfunctional acid anhydride) having two or more acid anhydride groups in the molecule. The acid anhydride (a2-2-1) preferably includes an acid anhydride having one or more cyclic acid anhydride groups in the molecule. The number of carbon atoms in the acid anhydride (a2-2-1) is not particularly limited, but is preferably 6 or more, more preferably 8 or more and preferably 25 or less, more preferably 18 or less.

The acid anhydride (a2-2-1) is not particularly limited, but includes the monofunctional acid anhydride and the polyfunctional acid anhydride as described above.

The monofunctional acid anhydride is not particularly limited, but examples thereof include maleic anhydride, phthalic anhydride, succinic anhydride, trimellitic anhydride, a compound represented by the following Formula (7), methylbicyclo[2.2.1]heptane-2,3-dicarboxylic anhydride, bicyclo[2.2.1]heptane-2,3-dicarboxylic anhydride, nadic anhydride, methylnadic anhydride, hexahydrophthalic anhydride, methylhexahydrophthalic anhydride, 1,2,3,6-tetrahydrophthalic anhydride, tetrapropenyl succinic anhydride (3-dodecenyl succinic anhydride), and octenyl succinic anhydride.

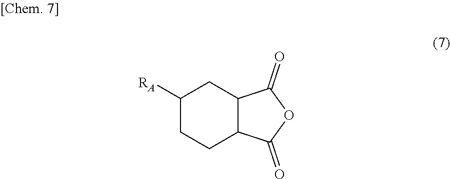

In Formula (7), RA represents a hydrogen atom or an alkyl group. The alkyl group is preferably an alkyl group having 1 to 12 carbon atoms, more preferably a methyl group. RA is also preferably a hydrogen atom. In other words, RA is preferably a hydrogen atom or a methyl group. The compound represented by Formula (7), where RA is a methyl group is 4-methylhexahydrophthalic anhydride. The compound represented by Formula (7), where RA is a hydrogen atom is hexahydrophthalic anhydride.

The polyfunctional acid anhydride is not particularly limited, but examples thereof include 1,2,3,4-butanetetracarboxylic dianhydride, ethylene glycol bisanhydrotrimellitate, glycerin bisanhydrotrimellitate monoacetate, 1,3,3a,4,5,9b-hexahydro-5 (tetrahydro-2,5-dioxo-3-furanyl) naphtho[1,2-C]furan-1,3-dione, pyromellitic anhydride, and benzophenonetetracarboxylic anhydride.

A commercially available product can be used as the acid anhydride. As succinic anhydride, for example, RIKACID SA manufactured by New Japan Chemical Co., Ltd. can be used. As 4-methylhexahydrophthalic anhydride, for example, RIKACID MH manufactured by New Japan Chemical Co., Ltd. can be used. As the hexahydrophthalic anhydride, for example, RIKACID HH manufactured by New Japan Chemical Co., Ltd. can be used. As 1,2,3,6-tetrahydrophthalic anhydride, for example, RIKACID TH manufactured by New Japan Chemical Co., Ltd. can be used. As tetrapropenyl succinic anhydride (3-dodecenyl succinic anhydride), for example, RIKACID DDSA manufactured by New Japan Chemical Co., Ltd. can be used. As octenyl succinic anhydride, for example, RIKACID OSA manufactured by New Japan Chemical Co., Ltd. can be used. As a mixture of methylbicyclo[2.2.1]heptane-2,3-dicarboxylic anhydride and bicyclo[2.2.1]heptane-2,3-dicarboxylic anhydride, for example, RIKACID HNA-100 manufactured by New Japan Chemical Co., Ltd. can be used. As a mixture of 4-methylhexahydrophthalic anhydride and hexahydrophthalic anhydride (mass ratio 70:30), for example, RIKACID MH-700 manufactured by New Japan Chemical Co., Ltd. can be used. As 1,2,3,4-butanetetracarboxylic dianhydride, for example, RIKACID BT-100 manufactured by New Japan Chemical Co., Ltd. can be used. As ethylene glycol bisanhydro trimellitate, for example, RIKACID TMEG-100, RIKACID TMEG-500, RIKACID TMEG-600, and RIKACID TMEG-S manufactured by New Japan Chemical Co., Ltd. can be used. As glycerin bisanhydro trimellitate monoacetate, for example, RIKACID TMTA-C manufactured by New Japan Chemical Co., Ltd. can be used. As 1,3,3a,4,5,9b-hexahydro-5 (tetrahydro-2,5-dioxo-3-furanyl) naphtho[1,2-C]furan-1,3-dione, for example, RIKACID TDA-100 manufactured by New Japan Chemical Co., Ltd. can be used.

The acid anhydride (a2-2-1) may be used singly or in combination of two or more kinds thereof.

In the reaction in a mixture containing the hydroxyl group-containing polyphenylene ether compound (a2-1-1) and the acid anhydride (a2-2-1) (the reaction of the hydroxyl group-containing polyphenylene ether compound (a2-1-1) with the acid anhydride (a2-2-1)), a catalyst may be used. The catalyst is not particularly limited as long as it is a catalyst that contributes to the progress of the reaction of the hydroxyl group-containing polyphenylene ether compound (a2-1-1) with the acid anhydride (a2-2-1). Examples of the catalyst include 2-ethyl-4-methylimidazole (2E4MZ).

The preliminary reaction product (A2-1) includes at least one of the reaction product (A2-1-4) and the reaction product (A2-1-5). In the reactions to obtain these reaction products, the hydroxyl group in the hydroxyl group-containing polyphenylene ether compound (a2-1-1) may act on the acid anhydride group in the acid anhydride (a2-2-1), the ring of the acid anhydride group may be opened, and an ester bond may be formed. In other words, the reaction product has an ester bond in the molecule. In this reaction, a carboxyl group is generated by ring opening of the acid anhydride group. From these facts, when the reaction proceeds suitably, an ester/carboxyl-modified polyphenylene ether compound having an ester bond and a carboxyl group in the molecule is obtained. Hence, the preliminary reaction product (A2-1) preferably includes an ester/carboxyl-modified polyphenylene ether compound having a terminal modified with a substituent having an ester bond and a carboxyl group.

The reaction product is not particularly limited as long as it is at least one of the reaction product (A2-1-4) and the reaction product (A2-1-5), but examples thereof include a compound obtained by reacting the hydroxyl group-containing polyphenylene ether compound (a2-1-1) with a compound represented by Formula (7) as the acid anhydride (a2-2-1) and a compound obtained by reacting the hydroxyl group-containing polyphenylene ether compound (a2-1-1) with octenyl succinic anhydride as the acid anhydride (a2-2-1). The compound obtained by reacting the hydroxyl group-containing polyphenylene ether compound (a2-1-1) with a compound represented by Formula (7) as the acid anhydride (a2-2-1) varies depending on the structure of the hydroxyl group-containing polyphenylene ether compound (a2-1-1) and the like, but examples thereof include a compound represented by the following Formula (8).

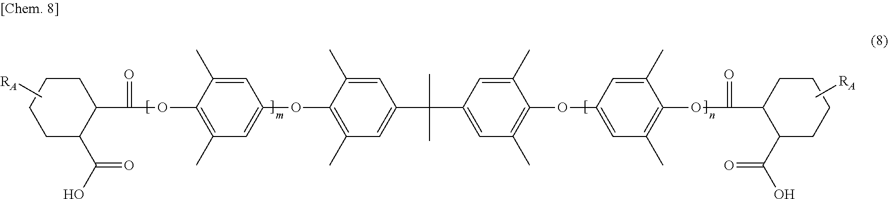

In Formula (8), RA includes those the same as RA in Formula (7), and specifically represents a hydrogen atom or an alkyl group. m and n are the same as m and n in Formulas (2) and (3), and specifically, m and n each preferably represent 0 to 20.

The equivalent ratio (acid anhydride group in acid anhydride (a2-2-1)/hydroxyl group in hydroxyl group-containing polyphenylene ether compound (a2-1-1)) of the acid anhydride groups in the acid anhydride (a2-2-1) to the hydroxyl groups in the hydroxyl group-containing polyphenylene ether compound (a2-1-1) is preferably 1.5 or less, more preferably 0.3 to 1.5, still more preferably 0.8 to 1. In other words, the amount of acid anhydride groups in the acid anhydride (a2-2-1) is preferably 1.5 equivalents or less, more preferably 0.3 to 1.5 equivalents, still more preferably 0.8 to 1 equivalent when the amount of hydroxyl groups in the hydroxyl group-containing polyphenylene ether compound (a2-1-1) is regarded as 1 equivalent. By blending the hydroxyl group-containing polyphenylene ether compound (a2-1-1) and the acid anhydride (a2-2-1) in the above range of equivalent ratio, a suitable preliminary reaction product is obtained. The equivalent is a relative value based on the reactive functional group, and the equivalent of hydroxyl groups in the hydroxyl group-containing polyphenylene ether compound can also be defined as the phenol equivalent.

The conditions for the reaction are not particularly limited as long as the reaction of the hydroxyl group-containing polyphenylene ether compound (a2-1-1) with the acid anhydride (a2-2-1) proceeds. As the conditions for the reaction, for example, conditions under which the ring opening rate of the acid anhydride (a2-2-1) is 80% to 100% are preferable. In the preliminary reaction, the ring is opened by the reaction of the acid anhydride (a2-2-1) with the hydroxyl group-containing polyphenylene ether compound (a2-1-1) as described above. For this reason, the degree of progress of the reaction can be examined by the ring opening rate of the acid anhydride (a2-2-1). In the preliminary reaction product, the ring opening rate of the acid anhydride (a2-2-1) is preferably 80% to 100% as described above. This decreases the amount of the acid anhydride (a2-2-1) remaining in the preliminary reaction product (A2-1) and can diminish adverse effects of the acid anhydride (a2-2-1). The ring opening rate of the acid anhydride (a2-2-1) can be calculated, for example, by comparing the infrared absorption spectra of the mixtures before and after the reaction. The mixture may have a peak attributed to a cyclic acid anhydride group at near 1800 to 1900 cm⁻¹ before and after the reaction (preliminary reaction). The mixture may have a peak attributed to a benzene ring not involved in the reaction at near 1450 to 1580 cm⁻¹. Then, using the peak attributed to the benzene ring as an internal standard, the amounts (relative values) of the peaks attributed to the acid anhydride group before and after the reaction are determined. The amount of a peak is determined by the area ratio using the internal standard. Specifically, the area (A1) of a peak attributed to the acid anhydride group before the reaction, the area (A2) of a peak attributed to the acid anhydride group after the reaction, the area (B1) of a peak attributed to the benzene ring before the reaction, and the area (B2) of a peak attributed to the benzene ring after the reaction are used. Thereupon, the area ratio (A1/B1) is the amount of acid anhydride group before the reaction, and the area ratio (A2/B2) is the amount of acid anhydride group after the reaction. These are substituted into the following equation.

$$Ring opening rate ( \% ) = \{ 1 - ( {A}_{2} / {B}_{2} ) / ( {A}_{1} / {B}_{1} ) \} \times 100$$

The ring opening rate of acid anhydride can be thus determined.

Since the ring opening rate of the acid anhydride (a2-2-1) changes depending on the heating temperature and heating time during preparation of the varnish, it is preferable to adjust the heating conditions appropriately so that the ring opening rate is as high as possible, and it is more preferable to adjust the heating conditions appropriately so that the ring opening rate is 80% or more. The conditions for this preliminary reaction can be appropriately set by sampling the reaction product over time while performing the preliminary reaction and confirming the ring opening rate.

The conditions for the reaction include the conditions described above, and more specifically, the reaction temperature is preferably 30° C. to 100° C., more preferably 60° C. to 80° C. When the reaction temperature is too low, the reaction tends to hardly proceed. When the reaction temperature is too high, the acid anhydride (a2-2-1) may volatilize before the acid anhydride (a2-2-1) reacts with the hydroxyl group-containing polyphenylene ether compound (a2-1-1). Hence, when the reaction temperature is in the above range, the hydroxyl group-containing polyphenylene ether compound (a2-1-1) can be suitably reacted with the acid anhydride (a2-2-1). The reaction time is preferably 2 to 10 hours, more preferably 3 to 6 hours. When the reaction time is in the above range, the hydroxyl group-containing polyphenylene ether compound (a2-1-1) can be suitably reacted with the acid anhydride (a2-2-1).

### (Preliminary Reaction Product (A2-2))

The preliminary reaction product (A2-2) is not particularly limited as long as it is a preliminary reaction product obtained by previously reacting a mixture containing a polyphenylene ether compound (a2-1-2) having at least one of a hydroxyl group and a carboxyl group in the molecule and a carbodiimide compound (a2-2-2). The preliminary reaction product (A2-2) is, for example, only required to be obtained by previously reacting the polyphenylene ether compound (a2-1-2) with the carbodiimide compound (a2-2-2), and may be a reaction product obtained by previously reacting the polyphenylene ether compound (a2-1-2) with the carbodiimide compound (a2-2-2) and also a compound (another raw material) (a2-3-2) capable of reacting with at least one of the polyphenylene ether compound (a2-1-2) and the carbodiimide compound (a2-2-2). Examples of the preliminary reaction product (A2-2) include a reaction product (A2-2-4) obtained by reacting the polyphenylene ether compound (a2-1-2) with the carbodiimide compound (a2-2-2) and a reaction product (A2-2-5) obtained by reacting the polyphenylene ether compound (a2-1-2) with the carbodiimide compound (a2-2-2) and the other raw material (a2-3-2). The mixture is only required to contain the polyphenylene ether compound (a2-1-2) and the carbodiimide compound (a2-2-2), and may further contain the other raw material (a2-3-2). The resin composition (A2-2) may contain the unreacted polyphenylene ether compound (a2-1-2), the unreacted carbodiimide compound (a2-2-2), or the unreacted other raw material (a2-3-2). The resin composition contains the reaction product [at least one of the reaction product (A2-2-4) and the reaction product (A2-2-5)] as the preliminary reaction product (A2-2), and may further contain the polyphenylene ether compound (a2-1-2) and the carbodiimide compound (a2-2-2). The resin composition may contain the other raw material (a2-3-2). The other raw material (a2-3-2) is not particularly limited as long as it is a compound capable of reacting with at least one of the polyphenylene ether compound (a2-1-2) and the carbodiimide compound (a2-2-2).

The carbodiimide compound (a2-2-2) is not particularly limited as long as it is a compound having a carbodiimide group (—N═C═N—) in the molecule. Examples of the carbodiimide compound (a2-2-2) include a cyclic carbodiimide compound. Examples of the cyclic carbodiimide compound include compounds having a carbodiimide group in the molecule and having a cyclic structure in which one nitrogen (first nitrogen) of the carbodiimide group and the other nitrogen (second nitrogen) are bonded via a bonding group. The cyclic carbodiimide compound may be a compound having one cyclic structure, or a compound having a plurality of cyclic structures.

The number of atoms forming the cyclic structure (the number of atoms in the cyclic structure) is not particularly limited, and is preferably 8 to 50, more preferably 10 to 30, still more preferably 10 to 20, particularly preferably 10 to 15, for example, from the viewpoints of stability and ease of production of the carbodiimide compound. The number of atoms in the cyclic structure means the number of atoms directly constituting the cyclic structure, for example, the number of atoms in the cyclic structure is 8 when the cyclic structure is an 8-membered ring, and the number of atoms in the cyclic structure is 50 when 5 the cyclic structure is a 0-membered ring. The molecular weight of the carbodiimide compound is not particularly limited, and is preferably 100 to 1,000, more preferably 100 to 750, still more preferably 250 to 750 from the viewpoints of stability and ease of production of the carbodiimide compound as with the number of atoms in the cyclic structure.

Examples of the cyclic structure include a structure represented by the following Formula (9). In other words, examples of the carbodiimide compound include a compound having a cyclic structure represented by the following Formula (9), and more specific examples thereof include a compound represented by the following Formula (9).

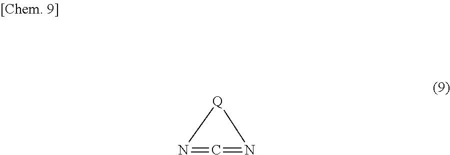

In Formula (9), Q represents the bonding group.

The bonding group is not particularly limited, and examples thereof include divalent to tetravalent aliphatic groups, divalent to tetravalent alicyclic groups, divalent to tetravalent aromatic groups, and any combination thereof. The aliphatic group is preferably, for example, a divalent to tetravalent aliphatic group having 1 to 20 carbon atoms. The alicyclic group is preferably, for example, a divalent to tetravalent alicyclic group having 3 to 20 carbon atoms. The aromatic group is preferably, for example, a divalent to tetravalent aromatic group having 5 to 15 carbon atoms. The bonding group may contain a heteroatom or a substituent. In other words, the aliphatic group, alicyclic group, and aromatic group constituting the bonding group may each contain a heteroatom or a substituent. Examples of the heteroatom include an oxygen atom, a nitrogen atom, a sulfur atom, a phosphorus atom, and a halogen atom. Examples of the substituent include an alkyl group having 1 to 20 carbon atoms, an aryl group having 6 to 15 carbon atoms, a nitro group, an amide group, a hydroxyl group, an ester group, an ether group, and an aldehyde group.

The aliphatic group is not particularly limited, and examples thereof include an alkylene group having 1 to 20 carbon atoms, an alkanetriyl group having 1 to 20 carbon atoms, and an alkanetetrayl group having 1 to 20 carbon atoms. Examples of the alkylene group include a methylene group, an ethylene group, a propylene group, a butylene group, a pentylene group, a hexylene group, a heptylene group, an octylene group, a nonylene group, a decylene group, a dodecylene group, and a hexadecylene group. Examples of the alkanetriyl group include a methanetriyl group, an ethanetriyl group, a propanetriyl group, a butanetriyl group, a pentanetriyl group, a hexanctriyl group, a heptanetriyl group, an octanetriyl group, a nonanetriyl group, a decantriyl group, a dodecanetriyl group, and a hexadecantriyl group. Examples of the alkanetetrayl group include a methanetetrayl group, an ethanetetrayl group, a propanetetrayl group, a butanetetrayl group, a pentanetetrayl group, a hexanetetrayl group, a heptanetetrayl group, an octanetetrayl group, a nonanetetrayl group, a decanetetrayl group, a dodecanetetrayl group, and a hexadecanetetrayl group. These aliphatic groups may contain a halogen atom. Examples of the heteroatom include an oxygen atom, a nitrogen atom, a sulfur atom, a phosphorus atom, and a halogen atom. These aliphatic groups may contain a substituent. Examples of the substituent include an alkyl group having 1 to 20 carbon atoms, an aryl group having 6 to 15 carbon atoms, a nitro group, an amide group, a hydroxyl group, an ester group, an ether group, and an aldehyde group.

The alicyclic group is not particularly limited, and examples thereof include a cycloalkylene group having 3 to 20 carbon atoms, a cycloalkanetriyl group having 3 to 20 carbon atoms, and a cycloalkanetetrayl group having 3 to 20 carbon atoms. Examples of the cycloalkylene group include a cyclopropylene group, a cyclobutylene group, a cyclopentylene group, a cyclohexylene group, a cycloheptylene group, a cyclooctylene group, a cyclononylene group, a cyclodecylene group, a cyclododecylene group, and a cyclohexadecylene group. Examples of the alkanetriyl group include a cyclopropanetriyl group, a cyclobutanetriyl group, a cyclopentanetriyl group, a cyclohexanetriyl group, a cycloheptanetriyl group, a cyclooctanetriyl group, a cyclononanetriyl group, a cyclodecanetriyl group, a cyclododecanetriyl group, and a cyclohexadecanetriyl group. Examples of the alkanetetrayl group include a cyclopropanetetrayl group, a cyclobutanetetrayl group, a cyclopentanetetrayl group, a cyclohexanetetrayl group, a cycloheptanetetrayl group, a cyclooctanetetrayl group, a cyclononanetetrayl group, a cyclodecanetetrayl group, a cyclododecanetetrayl group, and a cyclohexadecanetetrayl group. These alicyclic groups may contain a halogen atom and have a heterocyclic structure. Examples of the heteroatom include an oxygen atom, a nitrogen atom, a sulfur atom, a phosphorus atom, and a halogen atom. These alicyclic groups may contain a substituent. Examples of the substituent include an alkyl group having 1 to 20 carbon atoms, an aryl group having 6 to 15 carbon atoms, a nitro group, an amide group, a hydroxyl group, an ester group, an ether group, and an aldehyde group.

The aromatic group is not particularly limited, and examples thereof include an arylene group (arenediyl group) having 5 to 15 carbon atoms, an arenetriyl group having 5 to 15 carbon atoms, and an arenetetrayl group having 5 to 15 carbon atoms. The arylene group is divalent, and examples thereof include a phenylene group and a naphthalenediyl group. The arenetriyl group is trivalent, and examples thereof include a benzenetriyl group and a naphthalenetriyl group. The arenetetrayl group is tetravalent, and examples thereof include a benzenetetrayl group and a naphthalenetetrayl group. These aromatic groups may contain a halogen atom and have an aromatic heterocyclic structure. Examples of the heteroatom include an oxygen atom, a nitrogen atom, a sulfur atom, a phosphorus atom, and a halogen atom. These aromatic groups may contain a substituent. Examples of the substituent include an alkyl group having 1 to 20 carbon atoms, an aryl group having 6 to 15 carbon atoms, a nitro group, an amide group, a hydroxyl group, an ester group, an ether group, and an aldehyde group.

The carbodiimide compound may be used singly or in combination of two or more kinds thereof.

In the reaction in a mixture containing the polyphenylene ether compound (a2-1-2) and the carbodiimide compound (a2-2-2) (the reaction of the polyphenylene ether compound (a2-1-2) with the carbodiimide compound (a2-2-2)), a catalyst may be used. The catalyst is not particularly limited as long as it is a catalyst that contributes to the progress of the reaction of the polyphenylene ether compound (a2-1-2) with the carbodiimide compound (a2-2-2). The catalyst may be a catalyst that contributes to the progress of not only the reaction of the polyphenylene ether compound (a2-1-2) with the carbodiimide compound (a2-2-2) but also the reaction of the polyphenylene ether compound (a2-1-2) with the other raw material (a2-3-2) and the reaction of the carbodiimide compound (a2-2-2) with the other raw material (a2-3-2). Examples of the catalyst include 2-ethyl-4-methylimidazole (2E4MZ).

As described above, examples of the preliminary reaction product (A2-2) include the reaction product (A2-2-4) and the reaction product (A2-2-5). In the reaction to obtain these reaction products, the hydroxyl group and carboxyl group in the polyphenylene ether compound (a2-1-2) react with the carbodiimide group in the carbodiimide compound (a2-2-2) and the polyphenylene ether compound (a2-1-2) is bonded with the carbodiimide compound (a2-2-2). For example, the hydroxyl group reacts with the carbodiimide group to form an amide group, or the carboxyl group reacts with the carbodiimide group to form an ester bond. In a case where the carbodiimide compound (a2-2-2) is the cyclic carbodiimide compound, the hydroxyl group and carboxyl group in the polyphenylene ether compound (a2-1-2) may act on the carbodiimide group in the carbodiimide compound (a2-2-2), the ring of the carbodiimide compound (a2-2-2) may be opened, and an isocyanate group may be formed. In other words, in this case, the reaction product has an isocyanate group in the molecule. Hence, when the reaction proceeds suitably, an isocyanate-modified polyphenylene ether compound having an isocyanate group in the molecule is obtained. Hence, the preliminary reaction product (A2-2) preferably includes an isocyanate-modified polyphenylene ether compound having a terminal modified with a substituent having an isocyanate group. The preliminary reaction product (A2-2) may be a preliminary reaction product obtained by previously reacting a mixture containing the hydroxyl group-containing polyphenylene ether compound (a2-1-1), the acid anhydride (a2-2-1), and the carbodiimide compound (a2-2-2). The preliminary reaction product (A2-2) may be a preliminary reaction product obtained by previously reacting a mixture containing the hydroxyl group-containing polyphenylene ether compound (a2-1-1) and the acid anhydride (a2-2-1) and then previously reacting a mixture obtained by adding the carbodiimide compound (a2-2-2) to the obtained preliminary reaction product.

The reaction product is not particularly limited as long as it is at least one of the reaction product (A2-2-4) and the reaction product (A2-2-5), but examples thereof include a compound obtained by reacting the polyphenylene ether compound (a2-1-2) with a compound represented by Formula (9) as the carbodiimide compound (a2-2-2). The compound obtained by reacting the polyphenylene ether compound (a2-1-2) with a compound represented by Formula (9) as the carbodiimide compound (a2-2-2) varies depending on the structure of the polyphenylene ether compound (a2-1-2) and the like, but examples thereof include a compound represented by the following Formula (10).

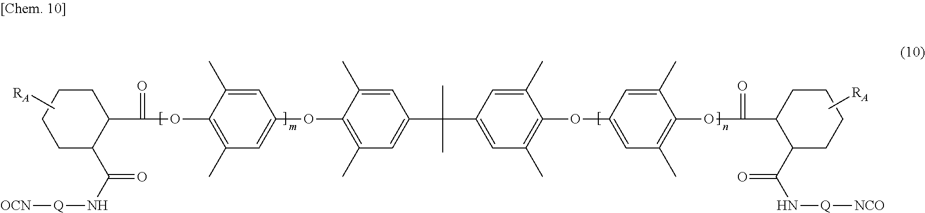

In Formula (10), RA includes those the same as RA in Formula (7), and specifically represents a hydrogen atom or an alkyl group. Q includes those the same as Q in Formula (9). m and n are the same as m and n in Formulas (2) and (3), and specifically, m and n each preferably represent 0 to 20.

The mass ratio of the polyphenylene ether compound (a2-1-2) to the carbodiimide compound (a2-2-2) (the polyphenylene ether compound (a2-1-2)/the carbodiimide compound (a2-2-2)) is preferably 20 to 200, more preferably 20 to 150, still more preferably 20 to 100. A too large amount of the polyphenylene ether compound (a2-1-2) remains when the amount of the polyphenylene ether compound (a2-1-2) is too large, and a too large amount of the carbodiimide compound (a2-2-2) remains when the amount of the carbodiimide compound (a2-2-2) is too large, and it tends to be difficult to obtain a suitable preliminary reaction product. Hence, by blending the polyphenylene ether compound (a2-1-2) and the carbodiimide compound (a2-2-2) in the above range of mass ratio, a suitable preliminary reaction product is obtained, and a resin composition having excellent performance and a cured product thereof can be obtained.

The conditions for the reaction are not particularly limited as long as the reaction of the polyphenylene ether compound (a2-1-2) with the carbodiimide compound (a2-2-2) proceeds. As the conditions for the reaction, for example, conditions under which the reaction rate is 60% to 100% are preferable. As the conditions for the reaction, for example, in a case where the carbodiimide compound (a2-2-2) is the cyclic carbodiimide compound, conditions under which the ring opening rate of the carbodiimide compound (a2-2-2) is 60% to 100% are preferable. In the preliminary reaction, the ring is opened by the reaction of the carbodiimide compound (a2-2-2) with the polyphenylene ether compound (a2-1-2) as described above. For this reason, the degree of progress of the reaction can be examined by the ring opening rate of the carbodiimide compound (a2-2-2). In the preliminary reaction product, the ring opening rate of the carbodiimide compound (a2-2-2) is preferably 60% to 100% as described above. When the reaction rate is as described above, the polyphenylene ether compound (a2-1-2) has a smaller number of hydroxyl groups and carboxyl groups and the adverse effects of these hydroxyl groups and carboxyl groups can be diminished. As a result, the interlayer adhesive properties can be more suitably enhanced, and further, the decrease in interlayer adhesive properties due to heating and moisture absorption can be suppressed. Hence, a resin composition is obtained which becomes a cured product, which is excellent in low dielectric properties and adhesive properties to metal foils and superior in interlayer adhesive properties and further has a further suppressed decrease in interlayer adhesive properties due to heating and moisture absorption. The reaction rate (for example, the ring opening rate of the carbodiimide compound (a2-2-2)) can be calculated, for example, by comparing the infrared absorption spectra of the mixtures before and after the reaction. The mixture may have a peak attributed to a carbodiimide group at near 2060 to 2210 cm⁻¹ before the reaction (preliminary reaction). The mixture may have a peak attributed to the bonding group that is not involved in the reaction at near 1450 to 1489 cm⁻¹. Then, using the peak attributed to the bonding group as an internal standard, the amounts (relative values) of the peaks attributed to the carbodiimide group before and after the reaction are determined. The amount of a peak is determined by the area ratio using the internal standard. Specifically, the area (C1) of a peak attributed to the carbodiimide group before the reaction, the area (C2) of a peak attributed to the carbodiimide group after the reaction, the area (D1) of a peak attributed to the bonding group before the reaction, and the area (D2) of a peak attributed to the bonding group after the reaction are used. Then, the area ratio (C1/D1) is the amount of carbodiimide groups before the reaction, and the area ratio (C2/D2) is the amount of carbodiimide groups after the reaction. These are substituted into the following equation.

$$Reaction rate ( \% ) = \{ 1 - ( {C}_{2} / {D}_{2} ) / ( {C}_{1} / {D}_{1} ) \} \times 100$$

By this, the reaction rate (the ring opening rate of the carbodiimide compound (a2-2-2)) can be determined.

Since the reaction rate (the ring opening rate of the carbodiimide compound (a2-2-2)) changes depending on the heating temperature and heating time during preparation of the varnish, it is preferable to adjust the heating conditions appropriately so that the ring opening rate is as high as possible, and it is more preferable to adjust the heating conditions appropriately so that the reaction rate is 60% or more. The conditions for this preliminary reaction can be appropriately set by sampling the reaction product over time while performing the preliminary reaction and examining the reaction rate.

The conditions for the reaction include the conditions described above, and more specifically, the reaction temperature is preferably 30° C. to 150° C., more preferably 50° C. to 120° C. When the reaction temperature is too low, the reaction tends to hardly proceed. When the reaction temperature is too high, the carbodiimide compound (a2-2-2) may decompose before the carbodiimide compound (a2-2-2) reacts with the polyphenylene ether compound (a2-1-2). Hence, when the reaction temperature is in the above range, the polyphenylene ether compound (a2-1-2) can be suitably reacted with the carbodiimide compound (a2-2-2). The reaction time is preferably 1 to 8 hours, more preferably 2 to 6 hours. When the reaction time is in the above range, the polyphenylene ether compound (a2-1-2) can be suitably reacted with the carbodiimide compound (a2-2-2).

The polyphenylene ether compound (A) may be used singly or in combination of two or more kinds thereof. Insulating layers of wiring boards used in various electronic devices are also required to have a property that smears generated by the drilling can be properly removed when drilling is performed using a drill, laser, or the like. Specifically, insulating layers of wiring boards are required to have a property (excellent desmear properties) that smears can be properly removed with permanganic acid or the like while damage to the insulating layers of wiring boards is suppressed. Hence, substrate materials for forming insulating layers of wiring boards are required to afford cured products exhibiting excellent desmear properties. From the viewpoint of enhancing the desmear properties, it is preferable to contain the preliminary reaction product (A2-1) and the preliminary reaction product (A2-2) and more preferable to contain the preliminary reaction product (A2-1) as the polyphenylene ether compound (A).

### (Reactive Compound (B))

The reactive compound (B) is not particularly limited as long as it is a reactive compound having an unsaturated double bond in the molecule. The reactive compound (B) is a compound that reacts with the polyphenylene ether compound (A). The reactive compound (B) may react with a benzoxazine compound (D) described later, and is a compound that is different from the benzoxazine compound (D) described later. In other words, the reactive compound (B) is a reactive compound having an unsaturated double bond in the molecule other than the benzoxazine compound (D) described later. The resin composition is a resin composition containing the polyphenylene ether compound (A) and the reactive compound (B). Examples of the reactive compound (B) include an allyl compound, an acrylate compound, a methacrylate compound, vinyl compounds such as a polybutadiene compound and a styrene compound, and a maleimide compound. The reactive compound (B) is preferably a maleimide compound among these.

The allyl compound is a compound having an allyl group in the molecule, and examples thereof include a triallyl isocyanurate compound such as triallyl isocyanurate (TAIC), a diallyl bisphenol compound, and diallyl phthalate (DAP).

The acrylate compound is a compound having an acryloyl group in the molecule, and examples thereof include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include diacrylate compounds such as tricyclodecanedimethanol diacrylate.

The methacrylate compound is a compound having a methacryloyl group in the molecule, and examples thereof include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate (DCP).

The vinyl compound is a compound having a vinyl group in the molecule. Examples of the vinyl compound include a monofunctional vinyl compound (monovinyl compound) having one vinyl group in the molecule and a polyfunctional vinyl compound having two or more vinyl groups in the molecule. Examples of the monofunctional vinyl compound include a styrene compound. Examples of the polyfunctional vinyl compound include a polyfunctional aromatic vinyl compound and a vinyl hydrocarbon-based compound. Examples of the vinyl hydrocarbon-based compound include divinylbenzene and a polybutadiene compound.

The maleimide compound is not particularly limited as long as it is a compound having a maleimide group in the molecule. Examples of the maleimide compound include a monofunctional maleimide compound having one maleimide group in the molecule, a polyfunctional maleimide compound having two or more maleimide groups in the molecule, and a modified maleimide compound. Examples of the modified maleimide compound include a modified maleimide compound in which a part of the molecule is modified with an amine compound, a modified maleimide compound in which a part of the molecule is modified with a silicone compound, and a modified maleimide compound in which a part of the molecule is modified with an amine compound and a silicone compound.

Examples of the maleimide compound include a maleimide compound having a phenylmaleimide group in the molecule, maleimide compounds having at least one of an alkyl group having 6 or more carbon atoms and an alkylene group having 6 or more carbon atoms in the molecule (a maleimide compound having an alkyl group having 6 or more carbon atoms in the molecule, a maleimide compound having an alkylene group having 6 or more carbon atoms in the molecule, and a maleimide compound having an alkyl group having 6 or more carbon atoms and an alkylene group having 6 or more carbon atoms in the molecule), a maleimide compound having a biphenylaralkyl structure in the molecule (biphenylaralkyl-type maleimide compound), and 1,6′-bismaleimide-(2,2,4-trimethyl) hexane.

Examples of the maleimide compound having a phenylmaleimide group in the molecule include 4,4′-diphenylmethanebismaleimide, polyphenylmethanemaleimide, m-phenylenebismaleimide, bisphenol A diphenyl ether bismaleimide, 3,3′-dimethyl-5,5′-diethyl-4,4′-diphenylmethanebismaleimide, 4-methyl-1,3-phenylenebismaleimide, and a maleimide compound having a phenylmaleimide group and an arylene structure substituted at the meta position in the molecule. The arylene structure bonded in the meta-orientation is an arylene group bonded in the meta-orientation, and examples thereof include m-arylene groups such as m-phenylene and m-naphthylene.

The alkyl group in the maleimide compound having at least one of an alkyl group having 6 or more carbon atoms and an alkylene group having 6 or more carbon atoms in the molecule is not particularly limited as long as it is an alkyl group having 6 or more carbon atoms, and examples thereof include a hexyl group, a heptyl group, an octyl group, and an icosyl group. The alkylene group is not particularly limited as long as it is an alkylene group having 6 or more carbon atoms, and examples thereof include a hexylene group, a heptylene group, an octylene group, and an icosylene group. The maleimide compound having at least one of an alkyl group having 6 or more carbon atoms and an alkylene group having 6 or more carbon atoms in the molecule is not particularly limited, and examples thereof include long-chain alkyl bismaleimides.

A commercially available product can be used as the maleimide compound. Specifically, as 4,4′-diphenylmethanebismaleimide, for example, BMI-1000 manufactured by Daiwa Kasei Industry Co., Ltd.) can be used. As polyphenylmethane maleimide, for example, BMI-2300 manufactured by Daiwa Kasei Industry Co., Ltd. can be used. As m-phenylenebismaleimide, for example, BMI-3000 manufactured by Daiwa Kasei Industry Co., Ltd. can be used. As bisphenol A diphenyl ether bismaleimide, for example, BMI-4000 manufactured by Daiwa Kasei Industry Co., Ltd. can be used. As 3,3′-dimethyl-5,5′-diethyl-4,4′-diphenylmethanebismaleimide, for example, BMI-5100 manufactured by Daiwa Kasei Industry Co., Ltd. can be used. As 4-methyl-1,3-phenylenebismaleimide, for example, BMI-7000 manufactured by Daiwa Kasei Industry Co., Ltd. can be used. As 1,6′-bismaleimide-(2,2,4-trimethyl) hexane, for example, BMI-TMH manufactured by Daiwa Kasei Industry Co., Ltd. can be used. As the biphenylaralkyl-type maleimide compound, for example, MIR-3000-70T manufactured by Nippon Kayaku Co., Ltd. can be used. As the maleimide compound having at least one of an alkyl group having 6 or more carbon atoms and an alkylene group having 6 or more carbon atoms in the molecule, BMI-1500, BMI-1700, and BMI-689 manufactured by Designer Molecules Inc. can be used.

The reactive compound (B) may be used singly or in combination of two or more kinds thereof.

The reactive compound (B) preferably includes at least one (B1) [first maleimide compound (B1)] selected from the biphenyl aralkyl-type maleimide compound or the polyphenylmethanemaleimide from the viewpoint of obtaining a resin composition that becomes a cured product having a higher glass transition temperature. The reactive compound (B) more preferably includes the first maleimide compound (B1) and a maleimide compound (B2) [second maleimide compound (B2)] other than the first maleimide compound (B1). As the second maleimide compound (B2), for example, 3,3′-dimethyl-5,5′-diethyl-4,4′-diphenylmethanebismaleimide and the maleimide compound having at least one of an alkyl group having 6 or more carbon atoms and an alkylene group having 6 or more carbon atoms in the molecule are preferable. When the second maleimide compound (B2) is contained as the reactive compound (B) [that is, not only the first maleimide compound (B1) but also the second maleimide compound (B2) are contained as the reactive compound (B)], the uniformity of the components contained in the cured product of the obtained resin composition can be further enhanced and a more suitable cured product is obtained.

In a case where the first maleimide compound (B1) and the second maleimide compound (B2) are contained as the reactive compound (B), the content of the first maleimide compound (B1) is not particularly limited but is preferably 10 to 80 parts by mass, more preferably 25 to 60 parts by mass with respect to 100 parts by mass of the reactive compound (B) [with respect to 100 parts by mass of the total mass of the first maleimide compound (B1) and the second maleimide compound (B2)].

In a case where the amount of the first maleimide compound (B1) is too small, there is a tendency that the effect exhibited by concurrent use of the first maleimide compound (B1) and the second maleimide compound (B2) cannot be fully exerted. Specifically, in the cured product of the obtained resin composition, there is a tendency that the effect of enhancing the uniformity of the contained components cannot be fully exhibited. In a case where the amount of the first maleimide compound (B1) is too large, there is a tendency that the effect of enhancing the uniformity of the components contained in the cured product of the obtained resin composition cannot be fully exhibited, as in the case where the amount of the first maleimide compound (B1) is too small. From these facts, by setting the content of the first maleimide compound (B1) in the above range, there is obtained a resin composition that affords a cured product, which is excellent in low dielectric properties, adhesive properties to metal foils, and interlayer adhesive properties, further has a sufficiently suppressed decrease in interlayer adhesive properties due to heating and moisture absorption, and exhibiting higher uniformity.

### (Additive (C))

The additive (C) is at least one selected from the group consisting of a heavy metal deactivator (C1) having at least one of an amino group and a triazole structure and a phenolic hydroxyl group in the molecule, a phosphite-based antioxidant (C2) having a tertiary butyl group and a phosphite structure in the molecule, and a hindered phenol-based antioxidant (C3) having a tertiary butyl group and a phenolic hydroxyl group in the molecule. A heavy metal deactivator is a compound that chelates a heavy metal ion to form a stable product and thus diminishes the influence of the heavy metal ion. It is considered that by containing the heavy metal deactivator (C1) in the resin composition, the decrease in interlayer adhesive properties can be suppressed even when heavy metal ions such as copper ions, which are components that may decrease interlayer adhesive properties, are present in the cured product of the resin composition. An antioxidant is a compound that captures free radicals present in a system, suppresses thermal decomposition, and suppresses oxidative deterioration. It is considered that by containing the phosphite-based antioxidant (C2) in the resin composition, the decrease in interlayer adhesive properties can be suppressed even when compounds that generate free radicals, which are components that may decrease interlayer adhesive properties, and the like are present. It is considered that by also containing the hindered phenol-based antioxidant (C3) in the resin composition, the decrease in interlayer adhesive properties can be suppressed even when compounds that generate free radicals, which are components that may decrease interlayer adhesive properties, and the like are present. Furthermore, it is preferable to use at least one of the phosphite-based antioxidant (C2) and the hindered phenol-based antioxidant (C3) concurrently with the heavy metal deactivator (C1) as the additive (C) from the viewpoint of obtaining a cured product that has a sufficiently suppressed decrease in interlayer adhesive properties due to heating and moisture absorption.

The heavy metal deactivator (C1) is not particularly limited as long as it is a heavy metal deactivator having at least one of an amino group and a triazole structure and a phenolic hydroxyl group in the molecule. Examples of the heavy metal deactivator (C1) include a heavy metal deactivator having an amino group and a phenolic hydroxyl group in the molecule, a heavy metal deactivator having a triazole structure and a phenolic hydroxyl group in the molecule, and a heavy metal deactivator having an amino group, a triazole structure, and a phenolic hydroxyl group in the molecule. Specific examples of the heavy metal deactivator (C1) include 2-hydroxy-N-1H-1,2,4-triazol-3-ylbenzamide (for example, ADK STAB CDA-1 manufactured by ADEKA CORPORATION).

The phosphite-based antioxidant (C2) is not particularly limited as long as it is a phosphite-based antioxidant having a tertiary butyl (tert-butyl) group and a phosphite structure in the molecule. Specific examples of the phosphite-based antioxidant (C2) include 3,9-bis(2,4-di-tert-butylphenoxy)-2,4,8,10-tetraoxa-3,9-diphosphaspiro[5.5] undecane, 3,9-bis(2,6-di-tert-butyl-4-methylphenoxy)-2,4,8,10-tetraoxa-3,9-diphosphaspiro[5.5] undecane (for example, ADK STAB PEP-36 manufactured by ADEKA CORPORATION), 2,2′-methylenebis(4,6-di-tert-butylphenyl) 2-ethylhexyl phosphite (for example, ADK STAB HP-10 manufactured by ADEKA CORPORATION), and tris(2,4-di-tert-butylphenyl)phosphite (for example, ADK STAB 2112 and 2112RG manufactured by ADEKA CORPORATION).

The hindered phenol-based antioxidant (C3) is not particularly limited as long as it is a hindered phenol-based antioxidant having a tertiary butyl group and a phenolic hydroxyl group in the molecule. Specific examples of the hindered phenol-based antioxidant (C3) include 1,3,5-tris(3,5-di-tert-butyl-4-hydroxybenzyl)-1,3,5-triazine-2,4,6 (1H,3H,5H)-trione (for example, ADK STAB AO-20 manufactured by ADEKA CORPORATION), octadecyl-3-(3,5-di-tert-butyl-4-hydroxyphenyl) propionate (for example, ADK STAB AO-50, AO-50F, and AO-50T manufactured by ADEKA CORPORATION), pentaerythritol tetrakis[3-(3,5-di-tert-butyl-4-hydroxyphenyl) propionate] (for example, ADK STAB AO-60 and AO-60G manufactured by ADEKA CORPORATION), and 1,3,5-tris(3,5-di-tert-butyl-4-hydroxyphenylmethyl)-2,4,6-trimethylbenzene (for example, ADK STAB AO-330 manufactured by ADEKA CORPORATION).

The additive (C) may be used singly or in combination of two or more kinds thereof.

### (Benzoxazine Compound (D))

The resin composition may contain a benzoxazine compound (D). The benzoxazine compound (D) is not particularly limited as long as it is a compound having a benzoxazine ring in the molecule, and the benzoxazine compound (D) also includes, for example, benzoxazine resin. The benzoxazine compound (D) is a compound that reacts with at least one of the polyphenylene ether compound (A) and the reactive compound (B). The benzoxazine compound (D) is a compound that is different from the reactive compound (B). Examples of the benzoxazine compound (D) include a benzoxazine compound having a phenolphthalein structure in the molecule (phenolphthalein-type benzoxazine compound), a benzoxazine compound having an alkenyl group in the molecule, a bisphenol F-type benzoxazine compound, and a diaminodiphenylmethane (DDM)-type benzoxazine compound. More specific examples of the benzoxazine compound (D) include 3,3′-(methylene-1,4-diphenylene)bis(3,4-dihydro-2H-1,3-benzoxazine) (P-d type benzoxazine compound) and 2,2-bis(3,4-dihydro-2H-3-phenyl-1,3-benzoxazine) methane (F-a-type benzoxazine compound).

As the benzoxazine compound (D), a benzoxazine compound having an alkenyl group in the molecule is preferable among the exemplified benzoxazine compounds. The benzoxazine compound having an alkenyl group in the molecule is a compound having an alkenyl group and a benzoxazine group in the molecule, and examples thereof include a compound having a benzoxazine group having an alkenyl group in the molecule. The alkenyl group is not particularly limited, and examples thereof include an alkenyl group having 2 to 6 carbon atoms. Specific examples of the alkenyl group include a vinyl group, an allyl group, and a butenyl group, and among these, an allyl group is preferable. Examples of the benzoxazine compound (D) include compounds having a benzoxazine group having an alkenyl group in the molecule. Examples of the benzoxazine group (benzoxazine group having an alkenyl group) include a benzoxazine group represented by the following Formula (11) and a benzoxazine group represented by the following Formula (12). Examples of the benzoxazine compound (D) include a benzoxazine compound having a benzoxazine group represented by the following Formula (11) in the molecule, a benzoxazine compound having a benzoxazine group represented by the following Formula (12) in the molecule, and a benzoxazine compound having a benzoxazine group represented by the following Formula (11) and a benzoxazine group represented by the following Formula (12) in the molecule. Examples of the benzoxazine compound having a benzoxazine group represented by the following Formula (11) in the molecule include a benzoxazine compound represented by the following Formula (13).

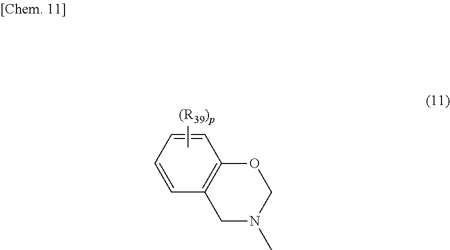

In Formula (11), R₃₉ represents an alkenyl group, and p represents 1 to 4. p is the average value of the degree of substitution of R₃₉, and is 1 to 4, preferably 1.

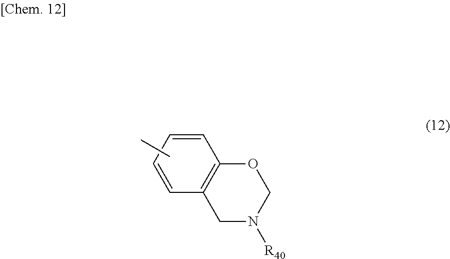

In Formula (12), R₄₀ represents an alkenyl group.

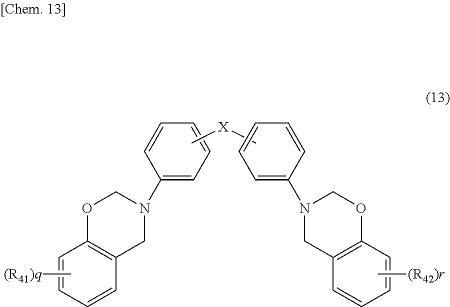

In Formula (13), R₄₁ and R₄₂ each independently represent an alkenyl group, X represents an alkylene group, and q and r each independently represent 1 to 4.

As described above, the alkenyl group in Formulas (11) to (13) is not particularly limited, but is preferably an allyl group.

The alkylene group is not particularly limited, and examples thereof include a methylene group, an ethylene group, a propylene group, a butylene group, a pentylene group, a hexylene group, a heptylene group, an octane group, an icosane group, and a hexatriacontane group. Among these, a methylene group is preferable.

q is the average value of the degree of substitution of R₄₁, and is 1 to 4, preferably 1. r is the average value of the degree of substitution of R₄₂, and is 1 to 4, preferably 1.

As the benzoxazine compound (D), a commercially available product can also be used, and for example, ALPd manufactured by SHIKOKU CHEMICALS CORPORATION may be used.

As the benzoxazine compound (D), the exemplified benzoxazine compounds may be used singly or in combination of two or more kinds thereof.

### (Content)

The content of the polyphenylene ether compound (A) is not particularly limited, but is preferably 20 to 80 parts by mass, more preferably 25 to 80 parts by mass, still more preferably 30 to 80 parts by mass with respect to 100 parts by mass of the sum of the polyphenylene ether compound (A) and the reactive compound (B). In a case where the resin composition contains the benzoxazine compound (D), the content of the polyphenylene ether compound (A) is not particularly limited, but is preferably 20 to 80 parts by mass, more preferably 20 to 75 parts by mass, still more preferably 25 to 70 parts by mass with respect to 100 parts by mass of the sum of the polyphenylene ether compound (A), the reactive compound (B), and the benzoxazine compound (D).

The content of the reactive compound (B) is not particularly limited, but is preferably 20 to 80 parts by mass, more preferably 20 to 75 parts by mass, still more preferably 20 to 70 parts by mass with respect to 100 parts by mass of the sum of the polyphenylene ether compound (A) and the reactive compound (B). In a case where the resin composition contains the benzoxazine compound (D), the content of the reactive compound (B) is not particularly limited, but is preferably is preferably 20 to 75 parts by mass, more preferably 25 to 75 parts by mass, still more preferably 25 to 70 parts by mass with respect to 100 parts by mass of the sum of the polyphenylene ether compound (A), the reactive compound (B), and the benzoxazine compound (D). In a case where the resin composition contains the benzoxazine compound (D) and the reactive compound (B) includes a maleimide compound (a case where the reactive compound (B) is a maleimide compound), the content of the maleimide compound is not particularly limited, but is preferably 20 to 75 parts by mass, more preferably 25 to 75 parts by mass, still more preferably 25 to 70 parts by mass with respect to 100 parts by mass of the sum of the polyphenylene ether compound (A), the reactive compound (B), and the benzoxazine compound (D).

The content of the additive (C) is not particularly limited, but is preferably 0.1 to 10 parts by mass, more preferably 0.1 to 8 parts by mass, still more preferably 0.1 to 5 parts by mass with respect to 100 parts by mass of the sum of the polyphenylene ether compound (A) and the reactive compound (B). In a case where the resin composition contains the benzoxazine compound (D), the content of the additive (C) is not particularly limited, but is preferably 0.1 to 10 parts by mass, more preferably 0.1 to 8 parts by mass, still more preferably 0.1 to 5 parts by mass with respect to 100 parts by mass of the sum of the polyphenylene ether compound (A), the reactive compound (B), and the benzoxazine compound (D).

In a case where the resin composition contains the benzoxazine compound (D), the content of the benzoxazine compound (D) is not particularly limited, but is preferably 1 to 40 parts by mass, more preferably 3 to 30 parts by mass, still more preferably 3 to 20 parts by mass with respect to 100 parts by mass of the sum of the polyphenylene ether compound (A), the reactive compound (B), and the benzoxazine compound (D).

When the amount of the polyphenylene ether compound (A) is too small, that is, the sum of the reactive compound (B) and the benzoxazine compound (D) is too large, there is a tendency that the relative dielectric constant increases so that it is difficult to maintain excellent low dielectric properties or it is difficult to perform desmear. When the amount of the polyphenylene ether compound (A) is too large, that is, the sum of the reactive compound (B) and the benzoxazine compound (D) is too small, there is a tendency that it is too easy to perform desmear. In other words, when the amount of the reactive compound (B) is too small or the amount of the benzoxazine compound (D) is too small, there is a tendency that it is too easy to perform desmear. When the amount of the reactive compound (B) is too large or the amount of the benzoxazine compound (D) is too large, there is a tendency that the relative dielectric constant increases so that it is difficult to maintain excellent low dielectric properties or it is difficult to perform desmear.

When the amount of the additive (C) is too small, the effect exerted by the addition of the additive (C) is insufficient, and for example, there is a tendency that the decrease in interlayer adhesive properties due to heating and moisture absorption cannot be sufficiently suppressed. When the amount of the additive (C) is too large, there is a tendency that the effect exerted by the addition of the additive (C) is saturated. When the amount of the additive (C) is too large, there is a case where the amount of at least one of the polyphenylene ether compound (A), the reactive compound (B), and the benzoxazine compound (D) is small, and there is a tendency that defects due to a decrease in one of the components are generated in such a case.

Hence, when the content of each of the polyphenylene ether compound (A), the reactive compound (B), the additive (C), and the benzoxazine compound (D) is in the above range, a cured product is obtained which is excellent in adhesive properties to metal foils, interlayer adhesive properties, and desmear properties and further has a sufficiently suppressed decrease in interlayer adhesive properties due to heating and moisture absorption and in which the ease of desmear and the like are suitably adjusted while excellent low dielectric properties are maintained.

### (Inorganic Filler)

The resin composition may contain an inorganic filler or may not contain an inorganic filler, and preferably contains an inorganic filler. The inorganic filler is not particularly limited as long as it is an inorganic filler that can be used as an inorganic filler contained in a resin composition. Examples of the inorganic filler include metal oxides such as silica, alumina, titanium oxide, magnesium oxide and mica, metal hydroxides such as magnesium hydroxide and aluminum hydroxide, talc, aluminum borate, barium sulfate, aluminum nitride, boron nitride, barium titanate, magnesium carbonate such as anhydrous magnesium carbonate, and calcium carbonate. Among them, silica, metal hydroxides such as magnesium hydroxide and aluminum hydroxide, aluminum oxide, boron nitride, and barium titanate are preferable, and silica is more preferable. The silica is not particularly limited, and examples thereof include crushed silica, spherical silica, and silica particles.

The inorganic filler may be an inorganic filler subjected to a surface treatment or an inorganic filler not subjected to a surface treatment. Examples of the surface treatment include treatment with a silane coupling agent.

Examples of the silane coupling agent include a silane coupling agent having at least one functional group selected from the group consisting of a vinyl group, a styryl group, a methacryloyl group, an acryloyl group, a phenylamino group, an isocyanurate group, a ureido group, a mercapto group, an isocyanate group, an epoxy group, and an acid anhydride group. In other words, examples of this silane coupling agent include compounds having at least one of a vinyl group, a styryl group, a methacryloyl group, an acryloyl group, a phenylamino group, an isocyanurate group, a ureido group, a mercapto group, an isocyanate group, an epoxy group, and an acid anhydride group as a reactive functional group, and further a hydrolyzable group such as a methoxy group or an ethoxy group.

Examples of the silane coupling agent include vinyltriethoxysilane and vinyltrimethoxysilane as those having a vinyl group. Examples of the silane coupling agent include p-styryltrimethoxysilane and p-styryltriethoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilane and N-phenyl-3-aminopropyltriethoxysilane as those having a phenylamino group.

The average particle size of the inorganic filler is not particularly limited, and is preferably 0.05 to 10 μm, more preferably 0.1 to 8 μm. Here, the average particle size refers to the volume average particle size. The volume average particle size can be measured by, for example, a laser diffraction method and the like.

The resin composition may contain an inorganic filler as described above. In a case where the resin composition contains the inorganic filler, the content of the inorganic filler is not particularly limited, but is preferably 10 to 250 parts by mass, more preferably 40 to 200 parts by mass with respect to 100 parts by mass of the total mass of the polyphenylene ether compound (A) and the reactive compound (B). In a case where the resin composition contains the benzoxazine compound (D) and the inorganic filler, the content of the inorganic filler is not particularly limited, but is preferably 10 to 250 parts by mass, more preferably 40 to 200 parts by mass with respect to 100 parts by mass of the total mass of the polyphenylene ether compound (A), the reactive compound (B), and the benzoxazine compound (D).

### (Other Components)

The resin composition according to the present embodiment may contain components (other components) other than the polyphenylene ether compound (A), the reactive compound (B), and the benzoxazine compound (D), if necessary, as long as the effects of the present invention are not impaired. As the other components contained in the resin composition according to the present embodiment, for example, additives such as a reactive compound other than the reactive compound (B), a reaction initiator, a curing accelerator, a catalyst, a polymerization retarder, a polymerization inhibitor, a dispersant, a leveling agent, a silane coupling agent, an antifoaming agent, an antioxidant, a heat stabilizer, an antistatic agent, an ultraviolet absorber, a dye or a pigment, and a lubricant may be further contained in addition to an inorganic filler as described above.

The resin composition according to the present embodiment may contain a reactive compound (other reactive compound) other than the reactive compound (B). The other reactive compound is a compound that is different from the reactive compound (B) and the benzoxazine compound (D). The other reactive compound is not particularly limited, but examples thereof include an acenaphthylene compound, a cyanate ester compound, and an active ester compound. The other reactive compound may be used singly or in combination of two or more kinds thereof.

The acenaphthylene compound is a compound having an acenaphthylene structure in the molecule. Examples of the acenaphthylene compound include acenaphthylene, alkylacenaphthylenes, halogenated acenaphthylenes, and phenylacenaphthylenes. Examples of the alkyl acenaphthylenes include 1-methyl acenaphthylene, 3-methyl acenaphthylene, 4-methyl acenaphthylene, 5-methyl acenaphthylene, 1-ethyl acenaphthylene, 3-ethyl acenaphthylene, 4-ethyl acenaphthylene, and 5-ethyl acenaphthylene. Examples of the halogenated acenaphthylenes include 1-chloroacenaphthylene, 3-chloroacenaphthylene, 4-chloroacenaphthylene, 5-chloroaccnaphthylene, 1-bromoacenaphthylene, 3-bromoacenaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylacenaphthylene. The acenaphthylene compound may be a monofunctional acenaphthylene compound having one acenaphthylene structure in the molecule as described above or may be a polyfunctional acenaphthylene compound having two or more acenaphthylene structures in the molecule.

The cyanate ester compound is a compound having a cyanato group in the molecule, and examples thereof include 2,2-bis(4-cyanatophenyl) propane, bis(3,5-dimethyl-4-cyanatophenyl) methane, and 2,2-bis(4-cyanatophenyl) ethane.

The active ester compound is a compound having an ester group exhibiting high reaction activity in the molecule, and examples thereof include a benzenecarboxylic acid active ester, a benzenedicarboxylic acid active ester, a benzenetricarboxylic acid active ester, a benzenetetracarboxylic acid active ester, a naphthalenecarboxylic acid active ester, a naphthalenedicarboxylic acid active ester, a naphthalenetricarboxylic acid active ester, a naphthalenetetracarboxylic acid active ester, a fluorenecarboxylic acid active ester, a fluorenedicarboxylic acid active ester, a fluorenetricarboxylic acid active ester, and a fluorenetetracarboxylic acid active ester.

As described above, the resin composition according to the present embodiment may contain a reaction initiator. The curing reaction can proceed even though the resin composition does not contain a reaction initiator. However, a reaction initiator may be added since there is a case where it is difficult to raise the temperature until curing proceeds depending on the process conditions. The reaction initiator is not particularly limited as long as it can promote the curing reaction of the resin composition, and examples thereof include a peroxide and an organic azo compound. Examples of the peroxide include dicumyl peroxide, α,α′-bis(t-butylperoxy-m-isopropyl)benzene, 2,5-dimethyl-2,5-di(t-butylperoxy)-3-hexyne, and benzoyl peroxide. Examples of the organic azo compound include azobisisobutyronitrile. A metal carboxylate can be concurrently used if necessary. By doing so, the curing reaction can be further promoted. Among them, α,α′-bis(t-butylperoxy-m-isopropyl)benzene is preferably used. α,α′-Bis(t-butylperoxy-m-isopropyl)benzene has a relatively high reaction initiation temperature and thus can suppress the promotion of the curing reaction at the time point at which curing is not required, for example, at the time of prepreg drying, and can suppress a decrease in storage stability of the resin composition. α,α′-Bis(t-butylperoxy-m-isopropyl)benzene exhibits low volatility, thus does not volatilize at the time of prepreg drying and storage, and exhibits favorable stability. The reaction initiators may be used singly or in combination of two or more kinds thereof.

As described above, the resin composition according to the present embodiment may contain a curing accelerator. The curing accelerator is not particularly limited as long as it can promote the curing reaction of the resin composition. Specific examples of the curing accelerator include imidazoles and derivatives thereof, organophosphorus compounds, amines such as secondary amines and tertiary amines, quaternary ammonium salts, organoboron compounds, and metal soaps. Examples of the imidazoles include 2-ethyl-4-methylimidazole, 2-methylimidazole, 2-phenyl-4-methylimidazole, 2-phenylimidazole, and 1-benzyl-2-methylimidazole. Examples of the organophosphorus compounds include triphenylphosphine, diphenylphosphine, phenylphosphine, tributylphosphine, and trimethylphosphine. Examples of the amines include dimethylbenzylamine, triethylenediamine, triethanolamine, and 1,8-diaza-bicyclo(5,4,0) undecene-7 (DBU). Examples of the quaternary ammonium salts include tetrabutylammonium bromide. Examples of the organoboron compounds include tetraphenylboron salts such as 2-ethyl-4-methylimidazole-tetraphenylborate and tetra-substituted phosphonium/tetra-substituted borate such as tetraphenylphosphonium/ethyltriphenylborate. The metal soap refers to a fatty acid metal salt, and may be a linear fatty acid metal salt or a cyclic fatty acid metal salt. Specific examples of the metal soaps include linear aliphatic metal salts and cyclic aliphatic metal salts having 6 to 10 carbon atoms. More specific examples thereof include aliphatic metal salts formed from linear fatty acids such as stearic acid, lauric acid, ricinoleic acid, and octylic acid and cyclic fatty acids such as naphthenic acid and metals such as lithium, magnesium, calcium, barium, copper, and zinc. Examples thereof include zinc octylate. The curing accelerators may be used singly or in combination of two or more kinds thereof.

As described above, the resin composition according to the present embodiment may contain a silane coupling agent. The silane coupling agent may be contained in the resin composition or may be contained as a silane coupling agent covered on the inorganic filler contained in the resin composition for surface treatment in advance. Among them, it is preferable that the silane coupling agent is contained as a silane coupling agent covered on the inorganic filler for surface treatment in advance, and it is more preferable that the silane coupling agent is contained as a silane coupling agent covered on the inorganic filler for surface treatment in advance and further is also contained in the resin composition. In the case of a prepreg, the silane coupling agent may be contained in the prepreg as a silane coupling agent covered on the fibrous base material for surface treatment in advance. Examples of the silane coupling agent include those similar to the silane coupling agents used in the surface treatment of the inorganic filler described above.

As described above, the resin composition according to the present embodiment may contain a flame retardant. The flame retardancy of a cured product of the resin composition can be enhanced by containing a flame retardant. The flame retardant is not particularly limited. Specifically, in the field in which halogen-based flame retardants such as bromine-based flame retardants are used, for example, ethylenedipentabromobenzene, ethylenebistetrabromoimide, decabromodiphenyloxide, and tetradecabromodiphenoxybenzene that have a melting point of 300° C. or more, and a bromostyrene-based compound that reacts with the polymerizable compound are preferable. It is considered that the elimination of halogen at a high temperature and the decrease in heat resistance can be suppressed by the use of a halogen-based flame retardant. There is a case where a flame retardant containing phosphorus (phosphorus-based flame retardant) is used in fields required to be halogen-free. The phosphorus-based flame retardant is not particularly limited, and examples thereof include a phosphate ester-based flame retardant, a phosphazene-based flame retardant, a bis(diphenylphosphine oxide)-based flame retardant, and a phosphinate-based flame retardant. Specific examples of the phosphate ester-based flame retardant include a condensed phosphate ester such as dixylenyl phosphate. Specific examples of the phosphazene-based flame retardant include phenoxyphosphazene. Specific examples of the bis(diphenylphosphine oxide)-based flame retardant include xylylenebis(diphenylphosphine oxide). Specific examples of the phosphinate-based flame retardant include metal phosphinates such as an aluminum dialkyl phosphinate. As the flame retardant, the respective flame retardants exemplified may be used singly or in combination of two or more kinds thereof.

### (Use)

The resin composition is used when a prepreg is manufactured, as described later. The resin composition is used when a resin layer included in a metal foil with resin and a film with resin is formed and when an insulating layer included in a metal-clad laminate and a wiring board is formed. As described above, the resin composition affords a cured product exhibiting excellent low dielectric properties such as a low relative dielectric constant. For this reason, the resin composition is suitably used to form an insulating layer included in a wiring board compatible with high frequencies, such as wiring boards for antennas and antenna boards for millimeter-wave radar. In other words, the resin composition is suitable for manufacture of wiring boards compatible with high frequencies.

### (Production Method)

The method for producing the resin composition is not particularly limited, and examples thereof include a method in which the polyphenylene ether compound (A), the reactive compound (B), the additive (C), and the benzoxazine compound (D) are mixed together so as to have predetermined contents. Examples thereof include the method to be described later in the case of obtaining a varnish-like composition containing an organic solvent.

By using the resin composition according to the present embodiment, a prepreg, a metal-clad laminate, a wiring board, a metal foil with resin, and a film with resin can be obtained as described below.

### [Prepreg]

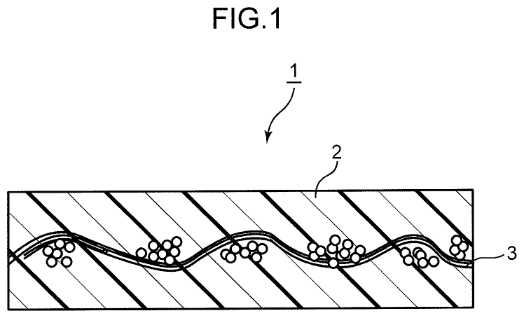

FIG. 1 is a schematic sectional view illustrating an example of a prepreg 1 according to an embodiment of the present invention.

As illustrated in FIG. 1, the prepreg 1 according to the present embodiment includes the resin composition or a semi-cured product 2 of the resin composition and a fibrous base material 3. This prepreg 1 includes the resin composition or the semi-cured product 2 of the resin composition and the fibrous base material 3 present in the resin composition or the semi-cured product 2 of the resin composition.

In the present embodiment, the semi-cured product is in a state in which the resin composition has been cured to an extent that the resin composition can be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, the semi-cured state includes a state where the viscosity has started to increase but curing is not completed, and the like.

The prepreg to be obtained using the resin composition according to the present embodiment may include a semi-cured product of the resin composition as described above or include the uncured resin composition itself. In other words, the prepreg may be a prepreg including a semi-cured product of the resin composition (the resin composition in B stage) and a fibrous base material or a prepreg including the resin composition before being cured (the resin composition in A stage) and a fibrous base material. The resin composition or a semi-cured product of the resin composition may be one obtained by drying or heating and drying the resin composition.

When a prepreg is manufactured, the resin composition 2 is often prepared in a varnish form and used in order to be impregnated into the fibrous base material 3 which is a base material for forming the prepreg. In other words, the resin composition 2 is usually a resin varnish prepared in a varnish form in many cases. Such a varnish-like resin composition (resin varnish) is prepared, for example, as follows.

First, the respective components which can be dissolved in an organic solvent are introduced into and dissolved in an organic solvent. At this time, heating may be performed if necessary. Thereafter, components which are used if necessary but are not dissolved in the organic solvent are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the polyphenylene ether compound (A), the reactive compound (B) and the like and does not inhibit the curing reaction. Specific examples thereof include toluene and methyl ethyl ketone (MEK).

Specific examples of the fibrous base material include glass cloth, aramid cloth, polyester cloth, a glass nonwoven fabric, an aramid nonwoven fabric, a polyester nonwoven fabric, pulp paper, and linter paper. When glass cloth is used, a laminate exhibiting excellent mechanical strength is obtained, and glass cloth subjected to flattening is particularly preferable. Specific examples of the flattening include a method in which glass cloth is continuously pressed at an appropriate pressure using a press roll to flatly compress the yarn. The thickness of the generally used fibrous base material is, for example, 0.01 mm or more and 0.3 mm or less. The glass fiber constituting the glass cloth is not particularly limited, and examples thereof include Q glass, NE glass, E glass, S glass, T glass, L glass, and L2 glass. The surface of the fibrous base material may be subjected to a surface treatment with a silane coupling agent. The silane coupling agent is not particularly limited, and examples thereof include a silane coupling agent having at least one selected from the group consisting of a vinyl group, an acryloyl group, a methacryloyl group, a styryl group, an amino group, and an epoxy group in the molecule.

The method for manufacturing the prepreg is not particularly limited as long as the prepreg can be manufactured. Specifically, when the prepreg is manufactured, the resin composition according to the present embodiment described above is often prepared in a varnish form and used as a resin varnish as described above.

Specific examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. Moreover, at this time, it is also possible to finally adjust the composition and impregnated amount to the desired composition and impregnated amount by repeating impregnation using a plurality of resin compositions having different compositions and concentrations.

The fibrous base material 3 impregnated with the resin composition (resin varnish) 2 is heated under desired heating conditions, for example, at 40° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the resin varnish.

The resin composition according to the present embodiment is a resin composition that affords a cured product, which is excellent in low dielectric properties, adhesive properties to metal foils, and interlayer adhesive properties and further has a sufficiently suppressed decrease in interlayer adhesive properties due to heating and moisture absorption. For this reason, the prepreg including this resin composition or a semi-cured product of this resin composition is a prepreg that affords a cured product, which is excellent in low dielectric properties, adhesive properties to metal foils, and interlayer adhesive properties and further has a sufficiently suppressed decrease in interlayer adhesive properties due to heating and moisture absorption. By using this prepreg, it is possible to suitably manufacture a wiring board including an insulating layer containing a cured product, which is excellent in low dielectric properties, adhesive properties to metal foils, and interlayer adhesive properties and further has a sufficiently suppressed decrease in interlayer adhesive properties due to heating and moisture absorption.

### [Metal-Clad Laminate]

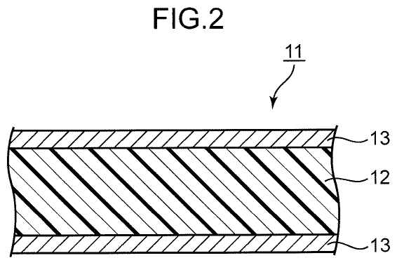

FIG. 2 is a schematic sectional view illustrating an example of a metal-clad laminate 11 according to an embodiment of the present invention.

As illustrated in FIG. 2, the metal-clad laminate 11 according to the present embodiment includes an insulating layer 12 containing a cured product of the resin composition and a metal foil 13 provided on the insulating layer 12. Examples of the metal-clad laminate 11 include a metal-clad laminate including an insulating layer 12 containing a cured product of the prepreg 1 illustrated in FIG. 1 and a metal foil 13 to be laminated together with the insulating layer 12. The insulating layer 12 may be formed of a cured product of the resin composition or a cured product of the prepreg. In addition, the thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μm. Examples of the metal foil 13 include a copper foil and an aluminum foil, and the metal foil 13 may be a copper foil with carrier which includes a release layer and a carrier for the improvement in handleability in a case where the metal foil is thin.

The method for manufacturing the metal-clad laminate 11 is not particularly limited as long as the metal-clad laminate 11 can be manufactured. Specific examples thereof include a method in which the metal-clad laminate 11 is fabricated using the prepreg 1. Examples of this method include a method in which the double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepregs 1, and laminating and integrating the metal foils 13 and prepregs 1 by heating and pressing. In other words, the metal-clad laminate 11 is obtained by laminating the metal foil 13 on the prepreg 1 and then performing heating and pressing. The heating and pressing conditions can be appropriately set depending on the thickness of the metal-clad laminate 11, the kind of the resin composition contained in the prepreg 1, and the like. For example, it is possible to set the temperature to 170° C. to 230° C., the pressure to 2 to 4 MPa, and the time to 60 to 150 minutes. Moreover, the metal-clad laminate may be manufactured without using a prepreg. Examples thereof include a method in which a varnish-like resin composition is applied on a metal foil to form a layer containing the resin composition on the metal foil and then heating and pressing is performed.

The resin composition according to the present embodiment is a resin composition that affords a cured product, which is excellent in low dielectric properties, adhesive properties to metal foils, and interlayer adhesive properties and further has a sufficiently suppressed decrease in interlayer adhesive properties due to heating and moisture absorption. For this reason, the metal-clad laminate including an insulating layer containing a cured product of this resin composition is a metal-clad laminate including an insulating layer containing a cured product, which is excellent in low dielectric properties, adhesive properties to metal foils, and interlayer adhesive properties and further has a sufficiently suppressed decrease in interlayer adhesive properties due to heating and moisture absorption. By using this metal-clad laminate, it is possible to suitably manufacture a wiring board including an insulating layer containing a cured product, which is excellent in low dielectric properties, adhesive properties to metal foils, and interlayer adhesive properties and further has a sufficiently suppressed decrease in interlayer adhesive properties due to heating and moisture absorption.

### [Wiring Board]

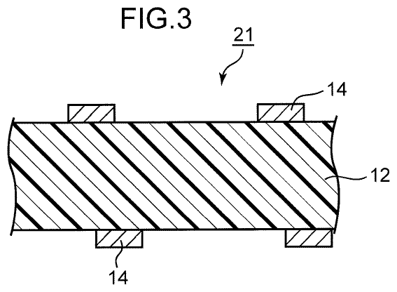

FIG. 3 is a schematic sectional view illustrating an example of a wiring board 21 according to an embodiment of the present invention.

As illustrated in FIG. 3, the wiring board 21 according to the present embodiment includes an insulating layer 12 containing a cured product of the resin composition and wiring 14 provided on the insulating layer 12. Examples of the wiring board 21 include a wiring board formed of an insulating layer 12 obtained by curing the prepreg 1 illustrated in FIG. 1 and wiring 14 which is laminated together with the insulating layer 12 and is formed by partially removing the metal foil 13. The insulating layer 12 may be formed of a cured product of the resin composition or a cured product of the prepreg.

The method for manufacturing the wiring board 21 is not particularly limited as long as the wiring board 21 can be manufactured. Specific examples thereof include a method in which the wiring board 21 is fabricated using the prepreg 1. Examples of this method include a method in which the wiring board 21, in which wiring is provided as a circuit on the surface of the insulating layer 12, is fabricated by forming wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above.

The wiring board 21 is a wiring board including the insulating layer 12 containing a cured product, which is excellent in low dielectric properties, adhesive properties to metal foils, and interlayer adhesive properties and further has a sufficiently suppressed decrease in interlayer adhesive properties due to heating and moisture absorption.

[Metal Foil with Resin]

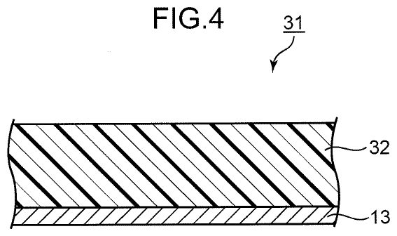

FIG. 4 is a schematic sectional view illustrating an example of a metal foil with resin 31 according to the present embodiment.

The metal foil with resin 31 according to the present embodiment includes a resin layer 32 containing the resin composition or a semi-cured product of the resin composition and a metal foil 13 as illustrated in FIG. 4. The metal foil with resin 31 includes the metal foil 13 on the surface of the resin layer 32. In other words, the metal foil with resin 31 includes the resin layer 32 and the metal foil 13 to be laminated together with the resin layer 32. The metal foil with resin 31 may include other layers between the resin layer 32 and the metal foil 13.

The resin layer 32 may contain a semi-cured product of the resin composition as described above or may contain the uncured resin composition. In other words, the metal foil with resin 31 may be a metal foil with resin including a resin layer containing a semi-cured product of the resin composition (the resin composition in B stage) and a metal foil or a metal foil with resin including a resin layer containing the resin composition before being cured (the resin composition in A stage) and a metal foil. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the metal foil, metal foils used in metal-clad laminates or metal foils with resin can be used without limitation. Examples of the metal foil include a copper foil and an aluminum foil.

The metal foil with resin 31 may include a cover film and the like if necessary. By including a cover film, it is possible to prevent entry of foreign matter and the like. The cover film is not particularly limited, and examples thereof include a polyolefin film, a polyester film, a polymethylpentene film, and films formed by providing a release agent layer on these films.

The method for manufacturing the metal foil with resin 31 is not particularly limited as long as the metal foil with resin 31 can be manufactured. Examples of the method for manufacturing the metal foil with resin 31 include a method in which the varnish-like resin composition (resin varnish) is applied on the metal foil 13 and heated to manufacture the metal foil with resin 31. The varnish-like resin composition is applied on the metal foil 13 using, for example, a bar coater. The applied resin composition is heated under the conditions of, for example, 40° C. or more and 180° C. or less and 0.1 minute or more and 10 minutes or less. The heated resin composition is formed as the uncured resin layer 32 on the metal foil 13. By the heating, the organic solvent can be decreased or removed by being volatilized from the resin varnish.

The resin composition according to the present embodiment is a resin composition that affords a cured product, which is excellent in low dielectric properties, adhesive properties to metal foils, and interlayer adhesive properties and further has a sufficiently suppressed decrease in interlayer adhesive properties due to heating and moisture absorption. For this reason, the metal foil with resin including a resin layer containing this resin composition or a semi-cured product of this resin composition is a metal foil with resin including a resin layer that affords a cured product, which is excellent in low dielectric properties, adhesive properties to metal foils, and interlayer adhesive properties and further has a sufficiently suppressed decrease in interlayer adhesive properties due to heating and moisture absorption. This metal foil with resin can be used when manufacturing a wiring board including an insulating layer containing a cured product, which is excellent in low dielectric properties, adhesive properties to metal foils, and interlayer adhesive properties and further has a sufficiently suppressed decrease in interlayer adhesive properties due to heating and moisture absorption. For example, by laminating the metal foil with resin on a wiring board, a multilayer wiring board can be manufactured. As the wiring board obtained using such a metal foil with resin, there is obtained a wiring board including an insulating layer containing a cured product, which is excellent in low dielectric properties, adhesive properties to metal foils, and interlayer adhesive properties and further has a sufficiently suppressed decrease in interlayer adhesive properties due to heating and moisture absorption.

[Film with Resin]

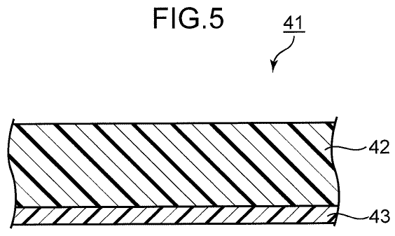

FIG. 5 is a schematic sectional view illustrating an example of a film with resin 41 according to the present embodiment.

The film with resin 41 according to the present embodiment includes a resin layer 42 containing the resin composition or a semi-cured product of the resin composition and a support film 43 as illustrated in FIG. 5. The film with resin 41 includes the resin layer 42 and the support film 43 to be laminated together with the resin layer 42. The film with resin 41 may include other layers between the resin layer 42 and the support film 43.

The resin layer 42 may contain a semi-cured product of the resin composition as described above or may contain the uncured resin composition. In other words, the film with resin 41 may be a film with resin including a resin layer containing a semi-cured product of the resin composition (the resin composition in B stage) and a support film or a film with resin including a resin layer containing the resin composition before being cured (the resin composition in A stage) and a support film. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the support film 43, support films used in films with resin can be used without limitation. Examples of the support film include electrically insulating films such as a polyester film, a polyethylene terephthalate (PET) film, a polyimide film, a polyparabanic acid film, a polyether ether ketone film, a polyphenylene sulfide film, a polyamide film, a polycarbonate film, and a polyarylate film.

The film with resin 41 may include a cover film and the like if necessary. By including a cover film, it is possible to prevent entry of foreign matter and the like. The cover film is not particularly limited, and examples thereof include a polyolefin film, a polyester film, and a polymethylpentene film.

The support film and the cover film may be those subjected to surface treatments such as a matt treatment, a corona treatment, a release treatment, and a roughening treatment if necessary.

The method for manufacturing the film with resin 41 is not particularly limited as long as the film with resin 41 can be manufactured. Examples of the method for manufacturing the film with resin 41 include a method in which the varnish-like resin composition (resin varnish) is applied on the support film 43 and heated to manufacture the film with resin 41. The varnish-like resin composition is applied on the support film 43 using, for example, a bar coater. The applied resin composition is heated under the conditions of, for example, 40° C. or more and 180° C. or less and 0.1 minute or more and 10 minutes or less. The heated resin composition is formed as the uncured resin layer 42 on the support film 43. By the heating, the organic solvent can be decreased or removed by being volatilized from the resin varnish.

The resin composition according to the present embodiment is a resin composition that affords a cured product, which is excellent in low dielectric properties, adhesive properties to metal foils, and interlayer adhesive properties and further has a sufficiently suppressed decrease in interlayer adhesive properties due to heating and moisture absorption. For this reason, the film with resin including a resin layer containing this resin composition or a semi-cured product of this resin composition is a film with resin including a resin layer that affords a cured product, which is excellent in low dielectric properties, adhesive properties to metal foils, and interlayer adhesive properties and further has a sufficiently suppressed decrease in interlayer adhesive properties due to heating and moisture absorption. This film with resin can be used when suitably manufacturing a wiring board including an insulating layer containing a cured product, which is excellent in low dielectric properties, adhesive properties to metal foils, and interlayer adhesive properties and further has a sufficiently suppressed decrease in interlayer adhesive properties due to heating and moisture absorption. A multilayer wiring board can be manufactured, for example, by laminating the film with resin on a wiring board and then peeling off the support film from the film with resin or by peeling off the support film from the film with resin and then laminating the film with resin on a wiring board. As the wiring board obtained using such a film with resin, there is obtained a wiring board including an insulating layer containing a cured product, which is excellent in low dielectric properties, adhesive properties to metal foils, and interlayer adhesive properties and further has a sufficiently suppressed decrease in interlayer adhesive properties due to heating and moisture absorption.

This specification discloses techniques in various aspects as described above, and the main techniques among these are summarized below.

A resin composition according to a first aspect is a resin composition that contains a polyphenylene ether compound (A), a reactive compound (B) having an unsaturated double bond in a molecule, and at least one additive (C) selected from the group consisting of a heavy metal deactivator (C1) having at least one of an amino group and a triazole structure and a phenolic hydroxyl group in a molecule, a phosphite-based antioxidant (C2) having a tertiary butyl group and a phosphite structure in a molecule, and a hindered phenol-based antioxidant (C3) having a tertiary butyl group and a phenolic hydroxyl group in a molecule.

A resin composition according to a second aspect is the resin composition according to the first aspect, in which the polyphenylene ether compound (A) includes at least one of a polyphenylene ether compound (A1) having at least one selected from the group consisting of a hydroxyl group, a carboxyl group, an unsaturated double bond group, and an ester bond in a molecule or a preliminary reaction product (A2) obtained by previously reacting a mixture containing a polyphenylene ether compound (a2-1) having at least one selected from the group consisting of a hydroxyl group, a carboxyl group, and an ester bond in a molecule and a compound (a2-2) that reacts with at least one of a hydroxyl group, a carboxyl group, and an ester bond.

A resin composition according to a third aspect is the resin composition according to the second aspect, in which the preliminary reaction product (A2) includes a preliminary reaction product obtained by previously reacting a polyphenylene ether compound having a hydroxyl group in a molecule and an acid anhydride having an acid anhydride group in a molecule.

A resin composition according to a fourth aspect is the resin composition according to any one of the first to third aspects, in which the reactive compound (B) includes at least one selected from the group consisting of an allyl compound, an acrylate compound, a methacrylate compound, a polybutadiene compound, a styrene compound, and a maleimide compound.

A resin composition according to a fifth aspect is the resin composition according to any one of the first to fourth aspects, in which a content of the polyphenylene ether compound (A) is 20 to 80 parts by mass with respect to 100 parts by mass of a sum of the polyphenylene ether compound (A) and the reactive compound (B).

A resin composition according to a sixth aspect is the resin composition according to any one of the first to fifth aspects, further containing a benzoxazine compound (D).

A resin composition according to a seventh aspect is the resin composition according to any one of the first to sixth aspects, containing at least one of the phosphite-based antioxidant (C2) and the hindered phenol-based antioxidant (C3) and the heavy metal deactivator (C1) as the additive (C).

A resin composition according to an eighth aspect is the resin composition according to any one of the first to seventh aspects, further containing an inorganic filler.

A resin composition according to a ninth aspect is the resin composition according to the eighth aspect, in which the inorganic filler is subjected to surface treatment with a silane coupling agent.

A prepreg according to a tenth aspect is a prepreg including the resin composition according to any one of the first to ninth aspects or a semi-cured product of the resin composition; and a fibrous base material.

A film with resin according to an eleventh aspect is a film with resin including a resin layer containing the resin composition according to any one of the first to ninth aspects or a semi-cured product of the resin composition; and a support film.

A film with resin according to a twelfth aspect is a metal foil with resin including a resin layer containing the resin composition according to any one of the first to ninth aspects or a semi-cured product of the resin composition; and a metal foil.

A metal-clad laminate according to a thirteenth aspect is a metal-clad laminate including an insulating layer containing a cured product of the resin composition according to any one of the first to ninth aspects; and a metal foil.

A metal-clad laminate according to a fourteenth aspect is a metal-clad laminate including an insulating layer containing a cured product of the prepreg according to the tenth aspect; and a metal foil.

A wiring board according to a fifteenth aspect is a wiring board including an insulating layer containing a cured product of the resin composition according to any one of the first to ninth aspects; and a wiring.

A wiring board according to a sixteenth aspect is a wiring board including an insulating layer containing a cured product of the prepreg according to the tenth aspect; and a wiring.

According to the present invention, it is possible to provide a resin composition that affords a cured product, which is excellent in low dielectric properties, adhesive properties to metal foils, and interlayer adhesive properties and further has a sufficiently suppressed decrease in interlayer adhesive properties due to heating and moisture absorption. Furthermore, according to the present invention, it is possible to provide a prepreg, a film with resin, a metal foil with resin, a metal-clad laminate, and a wiring board, which are obtained using the resin composition.

Hereinafter, the present invention will be described more specifically with reference to examples, but the scope of the present invention is not limited thereto.

### EXAMPLES

### Examples 1 to 7 and Comparative Examples 1 and 2

The respective components to be used when preparing a resin composition in the present examples will be described.

### (Polyphenylene Ether Compound (A))

Preliminary reaction product: Preliminary reaction product obtained by previously reacting polyphenylene ether compound having hydroxyl group in molecule and acid anhydride having acid anhydride group in molecule

The preliminary reaction product is specifically a preliminary reaction product obtained by conducting the reaction as follows.

The respective components used in the production of the preliminary reaction product will be described.

Polyphenylene ether compound having hydroxyl group in molecule: SA90 manufactured by SABIC Innovative Plastics Co., Ltd., number of terminal hydroxyl groups: 2, number average molecular weight Mn: 1700, phenol equivalent (hydroxyl group equivalent): 850 g/eq

Acid anhydride: Mixture of 4-methylhexahydrophthalic anhydride and hexahydrophthalic anhydride (mass ratio 70:30) (RIKACID MH-700 manufactured by New Japan Chemical Co., Ltd., monofunctional acid anhydride, liquid alicyclic acid anhydride, functional group equivalent of acid anhydride group: 161 to 166 g/eq, freezing point: 20° C.)

First, 84 parts by mass of the polyphenylene ether compound (SA90) having a hydroxyl group in the molecule and 16 parts by mass of the acid anhydride (RIKACID MH-700) were blended together, and this was diluted with toluene so that the solid concentration was 40% by mass. This was stirred and mixed using a disperser at a liquid temperature of 30° C. for 5 hours. By doing so, the polyphenylene ether compound having a hydroxyl group in the molecule reacted with the acid anhydride and a preliminary reaction product was obtained. The ring opening rate of the obtained preliminary reaction product (the ring opening rate acquired by the above-mentioned calculation method) was 91%.

The equivalent ratio of the hydroxyl groups in the polyphenylene ether compound having a hydroxyl group in the molecule to the acid anhydride groups in the acid anhydride is determined based on the functional groups (reactive groups) that undergo the reaction. In other words, the equivalent ratio presented in Table 1 is determined as the ratio of values acquired by dividing each blended amount by each functional group equivalent. The equivalent ratio is not calculated as an integer ratio or the like, but is a ratio determined by approximating the value appropriately by rounding off or the like. In other words, the equivalent ratio presented in Table 1 is a ratio determined by approximating the ratio of values acquired by dividing each blended amount by each functional group equivalent by rounding off. Specifically, the phenol equivalent (hydroxyl group equivalent) in the polyphenylene ether compound having a hydroxyl group in the molecule is 850 g/eq, and the functional group equivalent of the acid anhydride group in the acid anhydride is 161 to 166 g/eq. Here, the calculation is performed assuming that the functional group equivalent of the acid anhydride group in the acid anhydride is 163 g/eq. The blended amount of the polyphenylene ether compound having a hydroxyl group in the molecule is 84 parts by mass, and the blended amount of the acid anhydride is 16 parts by mass. From these facts, the equivalent ratio (the hydroxyl group equivalent in the polyphenylene ether compound having a hydroxyl group in the molecule: the acid anhydride group equivalent in the acid anhydride) is calculated to be (84/850): (16/163)=about 1:1. The equivalent ratio in the preliminary reaction product is thus 1:1. In other words, the equivalent ratio of the acid anhydride groups in the acid anhydride to the hydroxyl groups in the polyphenylene ether compound having a hydroxyl group in the molecule is 1.

The preliminary reaction product thus obtained is a preliminary reaction product obtained by previously reacting a mixture containing the polyphenylene ether compound having a hydroxyl group in the molecule and the acid anhydride (an ester/carboxyl-modified polyphenylene ether compound having a terminal modified with a substituent having an ester bond and a carboxyl group: a polyphenylene ether compound having a carboxyl group).

Modified PPE: Polyphenylene ether compound having vinylbenzyl group (ethenylbenzyl group) at molecular terminal (styrene-modified polyphenylene ether) (OPE-1200 manufactured by Mitsubishi Gas Chemical Company, Inc., number average molecular weight Mn: 1200, functional group equivalent of vinylbenzyl group: 670 g/eq)

(Reactive compound (B))
Maleimide compound 1: Biphenylaralkyl-Type Bismaleimide Compound (MIR-3000-70MT manufactured by Nippon Kayaku Co., Ltd., bismaleimide compound, functional group equivalent of maleimide group: 275 g/eq)
Maleimide compound 2:3,3′-Dimethyl-5,5′-diethyl-4,4′-diphenylmethanebismaleimide (BMI-5100 manufactured by Nippon Kayaku Co., Ltd., bismaleimide compound, functional group equivalent of maleimide group: 221 g/eq)

### (Benzoxazine Compound (D))

Benzoxazine compound: Benzoxazine compound having allyl group that is alkenyl group in molecule (alkenyl group-containing benzoxazine compound, benzoxazine compound represented by Formula (13), where X is methylene group, R₄₁ and R₄₂ are allyl group, and q and r are 1, ALPd manufactured by SHIKOKU CHEMICALS CORPORATION, functional group equivalent of benzoxazine group: 244 g/eq)

### (Additive (C))

Heavy metal deactivator: 2-Hydroxy-N-1H-1,2,4-triazol-3-ylbenzamide (ADK STAB CDA-1 manufactured by ADEKA CORPORATION)
Phosphite-based antioxidant: 2,2′-Methylenebis(4,6-di-tert-butylphenyl) 2-ethylhexyl phosphite (ADK STAB HP-10 manufactured by ADEKA CORPORATION)

### (Curing Accelerator)

2E4MZ: Imidazole-based curing accelerator (2-ethyl-4-methylimidazole, 2E4MZ manufactured by SHIKOKU CHEMICALS CORPORATION)

### (Inorganic Filler)

Inorganic filler: Spherical silica subjected to surface treatment with vinylsilane (SC2300-SVJ manufactured by ADMATECHS COMPANY LIMITED)

### (Preparation Method)

First, components other than the inorganic filler were added to methyl ethyl ketone (MEK) at the composition (parts by mass) presented in Table 1 so that the solid concentration was 60% by mass, and the mixture was stirred and mixed using a disperser for homogenization. The inorganic filler was added to the homogenized mixture at the composition (parts by mass) presented in Table 1, and the mixture was stirred and mixed using a disperser for 2 hours for homogenization. By doing so, a varnish-like resin composition (varnish) was obtained.

Next, a prepreg and evaluation substrates 1 and 2 (metal-clad laminates) were obtained as follows.

The obtained varnish was impregnated into a fibrous base material (glass cloth: “2116 type cloth” manufactured by Nitto Boseki Co., Ltd.) and then heated and dried at 150° C. using a non-contact type heating unit. By doing so, the solvent in the varnish was removed and the resin composition was semi-cured to obtain a prepreg (340 mm×510 mm). At that time, the content (resin content) of the components constituting the resin composition with respect to the prepreg was adjusted to be 47% by mass by the curing reaction.

Next, an evaluation substrate 1 (metal-clad laminate) was obtained as follows.

Copper foil (manufactured by Mitsui Mining & Smelting Co., Ltd., thickness: 35 μm, ST foil, one roughened surface) was disposed on both sides of each obtained prepreg so that the roughened surface was on the prepreg side. This as a body to be pressed was heated and pressed under the conditions of 200° C., 90 minutes, and a pressure of 2.94 MPa, thereby obtaining a copper-clad laminate (evaluation substrate 1: metal-clad laminate) having a copper foil bonded to both surfaces and a thickness of about 0.1 mm.

Next, the evaluation substrate 2 (metal-clad laminate) was obtained as follows.

Six sheets of each of the obtained prepregs were stacked, and copper foil (manufactured by Mitsui Mining & Smelting Co., Ltd., thickness: 35 μm, ST foil, one roughened surface) was disposed on both sides of the stacked body so that the roughened surface was on the prepreg side. This as a body to be pressed was heated and pressed under the conditions of 200° C., 90 minutes, and a pressure of 2.94 MPa, thereby obtaining a copper-clad laminate (evaluation substrate 2: metal-clad laminate) having a copper foil bonded to both surfaces and a thickness of about 0.6 mm.

Next, the evaluation substrate 3 (metal-clad laminate) was obtained as follows.

Stacked were eight sheets of each of the obtained prepregs, and copper foil (manufactured by Mitsui Mining & Smelting Co., Ltd., thickness: 35 μm, ST foil, one roughened surface) was disposed on both sides of the stacked body so that the roughened surface was on the prepreg side. This as a body to be pressed was heated and pressed under the conditions of 200° C., 90 minutes, and a pressure of 2.94 MPa, thereby obtaining a copper-clad laminate (evaluation substrate 3: metal-clad laminate) having a copper foil bonded to both surfaces and a thickness of about 0.8 mm.

The evaluation substrates 1 to 3 (copper-clad laminates) fabricated as described above were evaluated by the following methods.

### [Copper Foil Peel Strength]

The copper foil was peeled off from the evaluation substrate 1 (metal-clad laminate), and the peel strength at that time was measured in conformity with JIS C 6481. Specifically, the copper foil was peeled off from the evaluation substrate at a speed of 50 mm/min using a tensile tester, and the peel strength (N/mm) at that time was measured. This peel strength is the copper foil peel strength, and it can be seen that the adhesive properties of the metal foil (copper foil) are higher as this is higher.

### [Interlayer Peel Strength]

An unclad plate was obtained by removing the copper foil from the evaluation substrate 1 (metal-clad laminate) by etching. Prepregs were disposed on both surfaces of this unclad plate used as a core, and secondary molding was performed to obtain a laminate. The insulating layer (prepreg) on the uppermost surface was peeled off from this laminate at a speed of 50 mm/min using a tensile tester, and the peel strength (N/mm) at that time was measured. This peel strength is the interlayer peel strength in the normal state, and it can be seen that the interlayer adhesive properties in the normal state (that is, when neither moisture absorption treatment nor heat treatment has been performed) are higher as this value is higher.

[Interlayer Peel Strength after Moisture Absorption Treatment]

An unclad plate was obtained by removing the copper foil from the evaluation substrate 1 (metal-clad laminate) by etching. Prepregs were disposed on both surfaces of this unclad plate used as a core, and secondary molding was performed to obtain a laminate. This laminate was subjected to a moisture absorption treatment in which the laminate was left at 121° C. and a relative humidity of 100% for 72 hours, the insulating layer (prepreg) on the uppermost surface was peeled off from the laminate undergone this moisture absorption treatment at a speed of 50 mm/min using a tensile tester, and the peel strength (N/mm) at that time was measured. This peel strength is the interlayer peel strength after moisture absorption treatment, and it can be seen that the interlayer adhesive properties after moisture absorption treatment are higher as this is higher.

[Interlayer Peel Strength after Heat Treatment]

An unclad plate was obtained by removing the copper foil from the evaluation substrate 1 (metal-clad laminate) by etching. Prepregs were disposed on both surfaces of this unclad plate used as a core, and secondary molding was performed to obtain a laminate. This laminate was subjected to a heat treatment in which the laminate was left at 260° C. and a relative humidity of 0% for 1 hour, the insulating layer (prepreg) on the uppermost surface was peeled off from the laminate undergone this heat treatment at a speed of 50 mm/min using a tensile tester, and the peel strength (N/mm) at that time was measured. This peel strength is the interlayer peel strength after heat treatment, and it can be seen that the interlayer adhesive properties after heat treatment are higher as this is higher.

### [Desmear Properties]

First, the copper foil on the surface of the evaluation substrate 2 (copper-clad laminate) was removed by etching. As a desmear process, the substrate from which the copper foil was removed was immersed in a swelling liquid (Swelling Dip Securiganth P manufactured by Atotcch) at 60° C. for 5 minutes, then immersed in an aqueous potassium permanganate solution (Concentrate Compact CP manufactured by Atotech) at 80° C. for 10 minutes, and then subjected to neutralization. Before and after such a desmear process, the weight of the substrate was measured, and the amount of weight decrease (weight of substrate before desmear process-weight of substrate after desmear process) due to the desmear process was calculated, and the amount of weight decrease per 1 mm² (mg/mm²) was calculated from the amount of weight decrease. Based on the amount of weight decrease per 1 mm², evaluation was performed as follows.

It was evaluated as “A(x)” when the amount of weight decrease per 1 mm² was less than 15 mg/mm², it was evaluated as “B(◯)” when the amount of weight decrease per 1 mm² was 15 mg/mm² or more and less than 30 mg/mm², it was evaluated as “C(⊙)” when the amount of weight decrease per 1 mm² was 30 mg/mm² or more and less than 45 mg/mm², and it was evaluated as “D(x)” when the amount of weight decrease per 1 mm² was 45 mg/mm² or more.

The “A(x)” is not preferable since it is difficult to take off smear, and the “D(x)” is not preferable since the resin is excessively taken off and the shape of the vias and the like cannot be maintained. On the other hand, “B(◯)” and “C(⊙)” are preferable since smear can be removed while the shape of vias and the like can be maintained, and “C(⊙)” is more preferable from this point.

### [Relative Dielectric Constant Dk]

The relative dielectric constant (Dk) at 1 GHz was measured by the cavity perturbation method using an unclad plate obtained by removing the copper foil from the evaluation substrate 3 (copper-clad laminate) by etching as a test piece. Specifically, the relative dielectric constant (Dk) of the unclad plate (insulating layer included in the evaluation substrate 3) was measured at 1 GHz in conformity with IPC-TM-650 2.5.5.9 using “Impedance/Material Analyzer 4291A” manufactured by Hewlett-Packard Company. A relative dielectric constant of 3.4 or less is favorable.

The results of each evaluation are presented in Table 1.

TABLE 1

| | | | | | | | | | | Comparative | |
|---|---|---|---|---|---|---|---|---|---|---|---|
| | | | Examples | | | | | | | Example | |
| | | | 1 | 2 | 3 | 4 | 5 | 6 | 7 | 1 | 2 |
| Composition | Polyphenylene ether | Preliminary reaction | 15 | 15 | 30 | 30 | 30 | 60 | — | 15 | 30 |
| (parts by | compound | product | | | | | | | | | |
| mass) | | Modified PPE | 30 | 30 | 30 | 30 | 30 | — | 60 | 30 | 30 |
| | Reactive compound | Maleimide compound 1 | 20 | 20 | 15 | 15 | 15 | 15 | 15 | 20 | 15 |
| | | Maleimide compound 2 | 30 | 30 | 20 | 20 | 20 | 20 | 20 | 30 | 20 |
| | Benzoxazine compound | | 5 | 5 | 5 | 5 | 5 | 5 | 5 | 5 | 5 |
| | Curing accelerator | 2E4MZ | 0.3 | 0.3 | 0.3 | 0.3 | 0.3 | 0.3 | 0.3 | 0.3 | 0.3 |
| | Additive | Heavy metal deactivator | 1 | 3 | — | — | 0.5 | 0.5 | 0.5 | — | — |
| | | Phosphite-based antioxidant | — | — | 1 | 3 | 0.5 | 0.5 | 0.5 | — | — |

| | | | | | | | | | | |
|---|---|---|---|---|---|---|---|---|---|---|
| | Inorganic filler | 100 | 100 | 100 | 100 | 100 | 100 | 100 | 100 | 100 |
| Evaluation | Relative dielectric constant Dk | 3.3 | 3.3 | 3.2 | 3.2 | 3.2 | 3.4 | 3.1 | 3.3 | 3.3 |
| | Copper foil peel strength (N/mm) | 0.61 | 0.61 | 0.59 | 0.59 | 0.63 | 0.58 | 0.66 | 0.59 | 0.55 |
| | Interlayer peel strength (N/mm) | 0.36 | 0.38 | 0.41 | 0.42 | 0.45 | 0.40 | 0.51 | 0.31 | 0.27 |
| | Interlayer peel strength after moisture absorption | 0.36 | 0.35 | 0.41 | 0.41 | 0.43 | 0.39 | 0.49 | 0.07 | 0.05 |
| | treatment (N/mm) | | | | | | | | | |
| | Interlayer peel strength after heat treatment | 0.33 | 0.34 | 0.39 | 0.42 | 0.43 | 0.39 | 0.48 | 0.07 | 0.05 |
| | (N/mm) | | | | | | | | | |
| | Desmear properties | B | B | C | C | B | C | A | B | C |
| | | (◯) | (◯) | (⊙) | (⊙) | (◯) | (⊙) | (X) | (◯) | (⊙) |

As can be seen from Table 1, in a resin composition containing the polyphenylene ether compound (A) and the reactive compound (B), it has been found that in a case where the additive (C) is contained (Examples 1 to 7), a cured product is obtained which has copper foil peel strength and interlayer peel strength that are equal to or higher than those in a case where the additive (C) is not contained (Comparative Examples 1 and 2). It has been found that in Examples 1 to 7, a cured product is obtained which not only has high copper foil peel strength and high interlayer peel strength as described above but also has higher interlayer peel strength after moisture absorption treatment and higher interlayer peel strength after heat treatment than those in a case where the additive (C) is not contained (Comparative Examples 1 and 2). Specifically, when the contents of the polyphenylene ether compound (A) and the reactive compound (B) are the same, it is more clearly seen that in a case where the additive (C) is contained, a cured product is obtained which not only has higher copper foil peel strength and interlayer peel strength but also has higher interlayer peel strength after moisture absorption treatment and higher interlayer peel strength after heat treatment than those in a case where the additive (C) is not contained. More specifically, it has been found that in Examples 1 and 2, a cured product is obtained which not only has higher copper foil peel strength and higher interlayer peel strength but also has higher interlayer peel strength after moisture absorption treatment and higher interlayer peel strength after heat treatment than those in Comparative Example 1. It has been found that in Examples 3 and 4, a cured product is obtained which not only has higher copper foil peel strength and higher interlayer peel strength but also has higher interlayer peel strength after moisture absorption treatment and higher interlayer peel strength after heat treatment than those in Comparative Example 2. It has been found that in Examples 1 to 7, a cured product that is also excellent in low dielectric properties is obtained as the relative dielectric constant is as low as 3.4 or less. From these facts, it has been found that a resin composition becoming a cured product, which is excellent in low dielectric properties, adhesive properties to metal foils, and interlayer adhesive properties and further has a sufficiently suppressed decrease in interlayer adhesive properties due to heating and moisture absorption, is obtained by containing the additive (C).

It has been found that in a case where the heavy metal deactivator (C1) and the phosphite-based antioxidant (C2) are used concurrently as the additive (C) (Example 5), there is obtained a resin composition becoming a cured product, which is superior in adhesive properties to metal foils and interlayer adhesive properties and further has a more sufficiently suppressed decrease in interlayer adhesive properties due to heating and moisture absorption, as compared with a case where the content of the additive (C) is the same and one of the heavy metal deactivator (C1) and the phosphite-based antioxidant (C2) is contained as the additive (C) (Examples 1 and 3). From this fact, it has been found that it is preferable to use the heavy metal deactivator (C1) and the phosphite-based antioxidant (C2) concurrently as the additive (C).

Examples 1 to 6 are resin compositions that contain a preliminary reaction product obtained by previously reacting a polyphenylene ether compound having a hydroxyl group in the molecule and an acid anhydride having an acid anhydride group in the molecule as the polyphenylene ether compound (A). It has been found that in a case where such a preliminary reaction product is contained (Examples 1 to 6), there is obtained a cured product that is superior in desmear properties than those in a case where the preliminary reaction product is not contained but a polyphenylene ether compound other than the preliminary reaction product is contained (Example 7). From this fact, it has been found that a cured product, which not only is excellent in low dielectric properties, adhesive properties to metal foils, and interlayer adhesive properties and further has a sufficiently suppressed decrease in interlayer adhesive properties due to heating and moisture absorption but also is excellent in desmear properties, is obtained by containing the preliminary reaction product as the polyphenylene ether compound (A). In Example 7, it is more difficult to perform desmear than in Examples 1 to 6, but Example 7 is an excellent resin composition becoming a cured product, which is excellent in low dielectric properties, adhesive properties to metal foils, and interlayer adhesive properties and further has a sufficiently suppressed decrease in interlayer adhesive properties due to heating and moisture absorption.

This application is based on Japanese patent application No. 2022-134867 filed on Aug. 26, 2022, the contents of which are included in the present application.

In order to express the present invention, the present invention has been described above appropriately and sufficiently through the embodiments. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

According to the present invention, there is provided a resin composition that affords a cured product, which is excellent in low dielectric properties, adhesive properties to metal foils, and interlayer adhesive properties and further has a sufficiently suppressed decrease in interlayer adhesive properties due to heating and moisture absorption. In addition, the present invention provides a prepreg, a film with resin, a metal foil with resin, a metal-clad laminate, and a wiring board which are obtained using the resin composition.

1. A resin composition comprising:
a polyphenylene ether compound (A);
a reactive compound (B) having an unsaturated double bond in a molecule; and
at least one additive (C) selected from the group consisting of a heavy metal deactivator (C1) having at least one of an amino group and a triazole structure and a phenolic hydroxyl group in a molecule, a phosphite-based antioxidant (C2) having a tertiary butyl group and a phosphite structure in a molecule, and a hindered phenol-based antioxidant (C3) having a tertiary butyl group and a phenolic hydroxyl group in a molecule.

2. The resin composition according to claim 1, wherein the polyphenylene ether compound (A) includes at least one of a polyphenylene ether compound (A1) having at least one selected from the group consisting of a hydroxyl group, a carboxyl group, an unsaturated double bond group, and an ester bond in a molecule or a preliminary reaction product (A2) obtained by previously reacting a mixture containing a polyphenylene ether compound (a2-1) having at least one selected from the group consisting of a hydroxyl group, a carboxyl group, and an ester bond in a molecule and a compound (a2-2) that reacts with at least one of a hydroxyl group, a carboxyl group, and an ester bond.

3. The resin composition according to claim 2, wherein the preliminary reaction product (A2) includes a preliminary reaction product obtained by previously reacting a polyphenylene ether compound having a hydroxyl group in a molecule and an acid anhydride having an acid anhydride group in a molecule.

4. The resin composition according to claim 1, wherein the reactive compound (B) includes at least one selected from the group consisting of an allyl compound, an acrylate compound, a methacrylate compound, a polybutadiene compound, a styrene compound, and a maleimide compound.

5. The resin composition according to claim 1, wherein a content of the polyphenylene ether compound (A) is 20 to 80 parts by mass with respect to 100 parts by mass of a sum of the polyphenylene ether compound (A) and the reactive compound (B).

6. The resin composition according to claim 1, further comprising a benzoxazine compound (D).

7. The resin composition according to claim 1, comprising at least one of the phosphite-based antioxidant (C2) and the hindered phenol-based antioxidant (C3) and the heavy metal deactivator (C1) as the additive (C).

8. The resin composition according to claim 1, further comprising an inorganic filler.

9. The resin composition according to claim 8, wherein the inorganic filler is subjected to surface treatment with a silane coupling agent.

10. A prepreg comprising:
the resin composition according to claim 1 or a semi-cured product of the resin composition; and
a fibrous base material.

11. A film with resin comprising:
a resin layer containing the resin composition according to claim 1 or a semi-cured product of the resin composition; and
a support film.

12. A metal foil with resin comprising:
a resin layer containing the resin composition according to claim 1 or a semi-cured product of the resin composition; and
a metal foil.

13. A metal-clad laminate comprising:
an insulating layer containing a cured product of the resin composition according to claim 1; and
a metal foil.

14. A metal-clad laminate comprising:
an insulating layer containing a cured product of the prepreg according to claim 10; and
a metal foil.

15. A wiring board comprising:
an insulating layer containing a cured product of the resin composition according to claim 1; and
a wiring.

16. A wiring board comprising:
an insulating layer containing a cured product of the prepreg according to claim 10; and
a wiring.
